(19) United States
(12) Patent Application Publication
(10) Pub. No.: US 2026/0024589 A1
(43) Pub. Date: Jan. 22, 2026

(54) PAGE BUFFER CIRCUIT AND MEMORY DEVICE INCLUDING THE SAME

(71) Applicant: SAMSUNG ELECTRONICS CO., LTD., Suwon-si (KR)

(72) Inventors: Hyunkook Park, Suwon-si (KR); Hosang Cho, Suwon-si (KR); Jisang Lee, Suwon-si (KR)

(21) Appl. No.: 19/030,401

(22) Filed: Jan. 17, 2025

(30) Foreign Application Priority Data
Jul. 17, 2024 (KR) 10-2024-0094610

(51) Int. Cl. G11C 16/24; G11C 16/04

(52) U.S. Cl. CPC G11C 16/24; G11C 16/0483

(57) ABSTRACT

An example page buffer circuit includes a plurality of page buffer circuits and a plurality of cache latches connected with the plurality of page buffer circuits through a combined sensing node. Each of the plurality of page buffer circuits includes a main latch connected with a corresponding sensing node. The main latch includes a first transistor connected with a corresponding sensing node and configured to be driven by a monitoring signal, a first latch circuit configured to latch data, and a second transistor connected with the first transistor and configured to be driven by a voltage level of a node latching data in the first latch circuit, and a parasitic capacitor corresponding to a parasitic capacitance caused by a junction of the first transistor and the second transistor is connected between the first transistor and the second transistor.

### CROSS-REFERENCE TO RELATED APPLICATION

This application claims priority under 35 U.S.C. § 119 to Korean Patent Application No. 10-2024-0094610, filed on Jul. 17, 2024, in the Korean Intellectual Property Office, the disclosure of which is incorporated by reference herein in its entirety.

### BACKGROUND

Recently, as information communication devices are multifunctional, memory devices increase in capacity and are highly integrated. Memory devices may include a page buffer circuit for storing data in memory cells or outputting the data from the memory cells, and the page buffer circuit may include semiconductor devices such as transistors.

The page buffer circuit may be connected to a plurality of bit lines and may sense data of a plurality of memory cells through a plurality of bit lines.

### SUMMARY

The present disclosure relates to a page buffer circuit which may prevent charge sharing between a parasitic capacitor and a sensing node (or a combined sensing node) occurring in a discharging period of a data dumping operation.

In general, according to some aspects, a page buffer circuit includes a plurality of page buffer units and a plurality of cache latches connected to the plurality of page buffer units through a combined sensing node in common. Each of the plurality of page buffer units includes a main latch connected to a corresponding sensing node. The main latch includes a first transistor connected to a corresponding sensing node and driven by a monitoring signal, a first latch circuit configured to latch data, and a second transistor connected to the first transistor and driven by a voltage level of a node latching data in the first latch circuit, and a parasitic capacitor corresponding to a parasitic capacitance caused by a junction of the first transistor and the second transistor is connected between the first transistor and the second transistor.

In general, according to some aspects, a memory device includes a memory cell array including a plurality of memory cells and a page buffer circuit including a plurality of page buffer units respectively connected to the plurality of memory cells through a plurality of bit lines and a plurality of cache latches respectively corresponding to the plurality of page buffer units, wherein each of the plurality of page buffer units includes a main latch connected to a corresponding sensing node, the main latch includes a first transistor connected to a corresponding sensing node and driven by a monitoring signal, a first latch circuit configured to latch data, and a second transistor connected to the first transistor and driven by a voltage level of a node latching data in the first latch circuit, and a parasitic capacitor corresponding to a parasitic capacitance caused by a junction of the first transistor and the second transistor is connected between the first transistor and the second transistor.

In general, according to some aspects, a memory device includes a first semiconductor layer including a plurality of memory cells respectively connected to a plurality of bit lines and a second semiconductor layer disposed in a vertical direction with respect to the first semiconductor layer, the second semiconductor layer including a page buffer circuit, wherein the page buffer circuit includes a main region where a plurality of page buffer units are disposed and a cache region where a plurality of cache latches corresponding to the plurality of page buffer units are disposed, each of the plurality of page buffer units includes a main latch connected to a corresponding sensing node, the main latch includes a first transistor connected to a corresponding sensing node and driven by a monitoring signal, a first latch circuit configured to latch data, and a second transistor connected to the first transistor and driven by a voltage level of a node latching data in the first latch circuit, and a parasitic capacitor corresponding to a parasitic capacitance caused by a junction of the first transistor and the second transistor is connected between the first transistor and the second transistor.

### BRIEF DESCRIPTION OF THE DRAWINGS

Implementations will be more clearly understood from the following detailed description taken in conjunction with the accompanying drawings.

FIG. 1 is a block diagram illustrating an example of a memory device.

FIG. 2 is a circuit diagram illustrating an example of a memory block.

FIG. 3 illustrates an example of a connection between a memory cell array and a page buffer circuit.

FIG. 4 is a circuit diagram illustrating an example of a page buffer.

FIG. 5 is a circuit diagram illustrating in detail an example of a page buffer.

FIG. 6 is a circuit diagram illustrating in detail an example of a page buffer.

FIG. 7 illustrates a multi-stage structure of an example of a page buffer circuit.

FIG. 8 is a circuit diagram illustrating in detail an example of a sensing latch.

FIG. 9 is a circuit diagram illustrating in detail an example of a main latch.

FIGS. 10(a) and (b) is a diagram illustrating an example of a core operation sequence.

FIG. 11 is a circuit diagram describing an example of a data dumping operation between main latches.

FIG. 12 is a timing diagram of an example of a data dumping operation between main latches.

FIG. 13 is a circuit diagram describing an example of a data dumping operation between a main latch and a cache latch.

FIG. 14 is a timing diagram of an example of a data dumping operation of transferring data from a main latch to a cache latch.

FIG. 15 is a timing diagram of an example of a data dumping operation of transferring data from a cache latch to a main latch.

FIG. 16 is a circuit diagram illustrating in detail an example of a sensing latch.

FIG. 17 is a timing diagram of an example of a data dumping operation of transferring data from a sensing latch to a target latch.

FIG. 18 is a circuit diagram illustrating in detail an example of a cache latch.

FIG. 19 is a timing diagram of an example of a data dumping operation of transferring data from a cache latch to a target latch.

FIG. 20 is a flowchart illustrating an example of an operation of a page buffer circuit.

FIG. 21 illustrates an example of a memory device having a cell over peri (COP) structure

FIG. 22 is a cross-sectional view of an example of a memory device having a BVNAND structure.

FIG. 23 is a block diagram illustrating an example where a memory device is applied to a solid state drive (SSD) system.

### DETAILED DESCRIPTION

Herein, cases where an N-channel transistor is implemented as an N-type metal oxide semiconductor (NMOS) transistor and a P-channel transistor is implemented as a P-type metal oxide semiconductor (PMOS) transistor may be described for example, but implementations are not limited thereto. For example, in other implementations, an N-channel transistor and/or a P-channel transistor may be implemented as a transistor (for example, a junction field-effect transistor (JFET), a metal-semiconductor field-effect transistor (MESFET), a high electron mobility transistor (HEMT), or an insulated-gate bipolar transistor (IGBT)) which performs a switching operation and/or an amplification operation.

Hereinafter, implementations will be described in detail with reference to the accompanying drawings. Like reference numerals refer to like elements in the drawings, and their repeated descriptions are omitted.

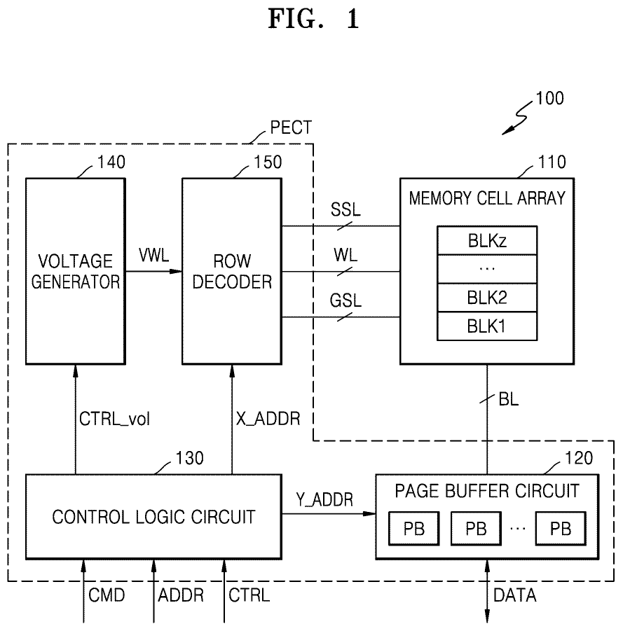

FIG. 1 is a block diagram illustrating an example of a memory device 100.

Referring to FIG. 1, the memory device 100 may include a memory cell array 110 and a peripheral circuit PECT. The peripheral circuit PECT may include a page buffer circuit 120, a control logic circuit 130, a voltage generator 140, and a row decoder 150. Herein, the memory device 100 may be referred to as a non-volatile memory device. Although not shown in FIG. 1, the peripheral circuit PECT may further include a data input/output (I/O) circuit or an I/O interface. Also, the peripheral circuit PECT may further include a column logic, a pre-decoder, a temperature sensor, a command decoder, and an address decoder.

The memory cell array 110 may include memory blocks BLK1 to BLKz (where z may be a positive integer), and each of the memory blocks BLK1 to BLKz may include memory cells. For example, the memory cells may be flash memory cells. Hereinafter, a case where memory cells are NAND flash memory cells will be described as an example of implementations. However, the present disclosure is not limited thereto, and in some implementations, memory cells may be resistive memory cells such as resistive random access memory (RAM) (ReRAM), phase change RAM (PRAM), or magnetic RAM (MRAM).

The page buffer circuit 120 may include page buffers PB. Each of the page buffers PB may be connected to memory cells of the memory cell array 110 through a corresponding bit line. The page buffer circuit 120 may select some bit lines BL from among a plurality of bit lines BL in response to a column address Y_ADDR received from the control logic circuit 130. Each of the page buffers PB may operate as a write driver or a sense amplifier. For example, in a program operation, each of the page buffers PB may apply a voltage, corresponding to data DATA which is to be programmed, to a bit line BL to store the data DATA in a memory cell. For example, in a program verify operation or a read operation, each of the page buffers PB may sense a current or a voltage through the bit line BL to sense programmed data DATA.

In some implementations, the page buffers PB may be disposed in a multi-stage structure, and each page buffer PB may have a page buffer unit-cache latch isolation structure where a cache latch and a page buffer unit including a main latch are disposed apart from each other. A plurality of cache latches arranged in one row in a multi-stage structure may share a combined sensing node, and thus, the page buffer circuit 120 may be implemented in a shared combined sensing node (SOC) structure.

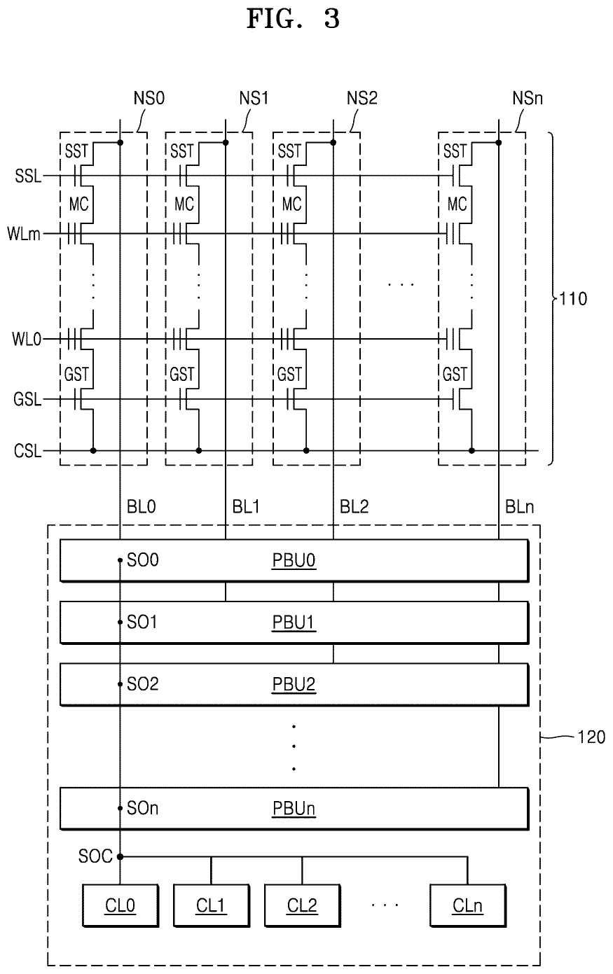

In some implementations, sensing nodes (for example, SO0 to SOn of FIG. 3) of page buffer units (for example, PBU0 to PBUn of FIG. 3) included in each of the plurality of page buffers PB may be electrically connected to one another through pass transistors. Cache latches (for example, CL0 to CLn of FIG. 3) included in each of the plurality of page buffers PB may be connected to the combined sensing node SOC in parallel. The page buffer units PBU0 to PBUn may respectively correspond to the cache latches CL0 to CLn. For example, the page buffer unit PBU0 may sense data through a corresponding bit line BL and may provide sensed data to a corresponding cache latch CL0.

In a sensing operation, the sensing nodes SO0 to SOn of the page buffer units PBU0 to PBUn included in each of the plurality of page buffers PB may be electrically disconnected from one another. In the sensing operation, each of the page buffer units PBU0 to PBUn may sense data through the bit line BL. In the sensing operation, the page buffer units PBU0 to PBUn may sense data in parallel.

In a data dumping operation, the page buffer units PBU0 to PBUn may sequentially transfer sensed data to the cache latches CL0 to CLn. In the data dumping operation, a sensing node of a page buffer unit may be connected to a combined sensing node connected to a cache latch.

The control logic circuit 130, for example, may output a voltage control signal CTRL_vol, a row address X_ADDR, and a column address Y_ADDR for a memory operation such as a program operation, a read operation, and/or an erase operation on the memory cell array 110, based on a command CMD, an address ADDR, and a control signal CTRL each received from a memory controller. The voltage generator 140 may generate word line voltages VWL for performing a memory operation, based on the voltage control signal CTRL_vol. In response to the row address X_ADDR received from the control logic circuit 130, the row decoder 150 may select one memory block from among the memory blocks BLK0 to BLKz, select one word line WL from among word lines WL of a selected memory block, and select one string selection line SSL from among string selection lines SSL.

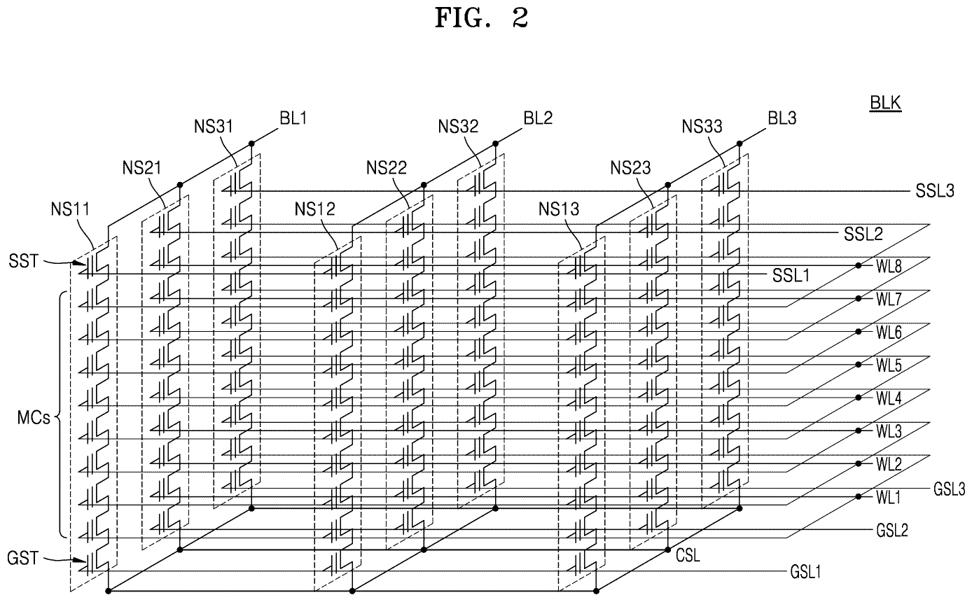

FIG. 2 is a circuit diagram illustrating an example of a memory block BLK.

Referring to FIG. 2, the memory block BLK may correspond to one of the memory blocks BLK1 to BLKz of FIG. 1. The memory block BLK may include NAND strings NS11 to NS33, and each NAND string (for example, NS11) may include a string selection transistor SST, memory cells MCs, and a ground selection transistor GST, which are serially connected to one another. The string and ground selection transistors SST and GST and the memory cells MCs each included in each NAND string may configure a structure where transistors are stacked in a vertical direction on a substrate.

The string selection transistor SST may be connected to corresponding string selection lines SSL1 to SSL3. The memory cells MCs may be respectively connected to corresponding word lines WL1 to WL8. The ground selection transistor GST may be connected to corresponding ground selection lines GSL1 to GSL3. The string selection transistor SST may be connected to a corresponding bit line, and the ground selection transistor GST may be connected to a common source line CSL. Here, the number of NAND strings, the number of word lines, the number of bit lines, the number of ground selection lines, and the number of string selection lines may be variously changed according to implementations.

U.S. Patent Publication Nos. 7,679,133, 8,553,466, 8,654,587 and 8,559,235 and U.S. Patent Application No. 2011/0233648 disclose appropriate elements of a three-dimensional (3D) memory array which includes a plurality of levels and in which word lines and/or bit lines are shared between the plurality of levels. In the present specification, the reference documents may be incorporated herein in their entirety by reference.

FIG. 3 illustrates an example of a connection between a memory cell array 110 and a page buffer circuit 120.

Referring to FIG. 3, the memory cell array 110 may include first to nth+1 NAND strings NS0 to NSn, and each of the first to nth+1 NAND strings NS0 to NSn may include a ground selection transistor GST connected to the ground selection line GSL, memory cells MC respectively connected to word lines WL0 to WLm, and a string selection transistor SST connected to the string selection line SSL (where n and m may be positive integers).

The page buffer circuit 120 may include first to nth+1 page buffer units PBU0 to PBUn. The first page buffer unit PBU0 may be connected to a first NAND string NS0 through a first bit line BL0, and the nth+1 page buffer unit PBUn may be connected to an nth+1 NAND string NSn through an nth+1 bit line BLn. The page buffer circuit 120 may further include first to nth+1 cache latches CL0 to CLn respectively corresponding to the first to nth+1 page buffer units PBU0 to PBUn. For example, the page buffer circuit 120 may have a structure where 8-stage page buffer units PBU0 to PBUn and 8-stage cache latches CL0 to CLn are arranged in one row.

The sensing nodes SO0 to SOn of the first to nth+1 page buffer units PBU0 to PBUn may be connected to the combined sensing node SOC in common, and the first to nth+1 cache latches CL0 to CLn may be connected to the combined sensing node SOC in common. Accordingly, the first to nth+1 page buffer units PBU0 to PBUn may be connected to the first to nth+1 cache latches CL0 to CLn through the combined sensing node SOC. Although not shown in FIG. 3, the first to nth+1 page buffer units PBU0 to PBUn may include at least one selection transistor which electrically connects the sensing nodes SO0 to SOn with each other.

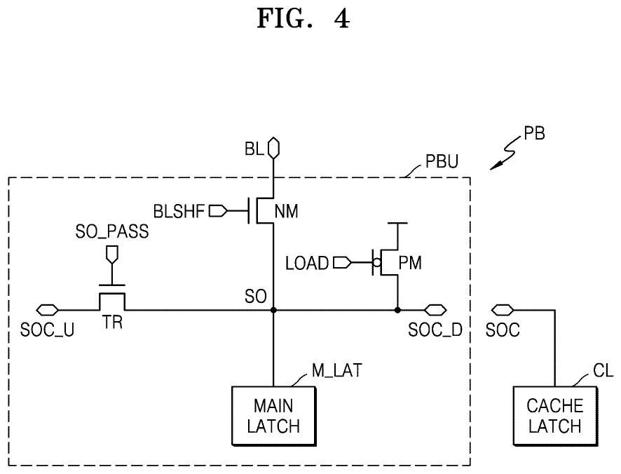

FIG. 4 is a circuit diagram illustrating an example of a page buffer PB.

Referring to FIG. 4, the page buffer PB may correspond to an example of the page buffer PB of FIG. 1. Also, the sensing node SO may correspond to one of the sensing nodes SO0 to SOn described above with reference to FIG. 3.

The page buffer PB may include a page buffer unit PBU and a cache latch CL. The cache latch CL may be connected to a data I/O line, and the cache latch CL may be disposed adjacent to the data I/O line. Therefore, the page buffer unit PBU and the cache latch CL may be disposed apart from each other, and the page buffer PB may have an isolation structure of page buffer unit PBU-cache latch CL.

The page buffer unit PBU may include a main latch M_LAT, a bit line shut-off transistor NM, a precharge transistor PM, and a pass transistor TR. The bit line shut-off transistor NM may be connected to a bit line BL and may be driven by a bit line shut-off signal BLSHF. When the bit line shut-off transistor NM is turned on, the sensing node SO may be connected to the bit line BL. The precharge transistor PM may be driven by a load signal LOAD, and when the precharge transistor PM is turned on, the sensing node SO may be precharged. The pass transistor TR may be driven by a pass control signal SO_PASS, and when the pass transistor TR is turned on, the sensing node SO may be connected to first and second terminals SOC_U and SOC_D.

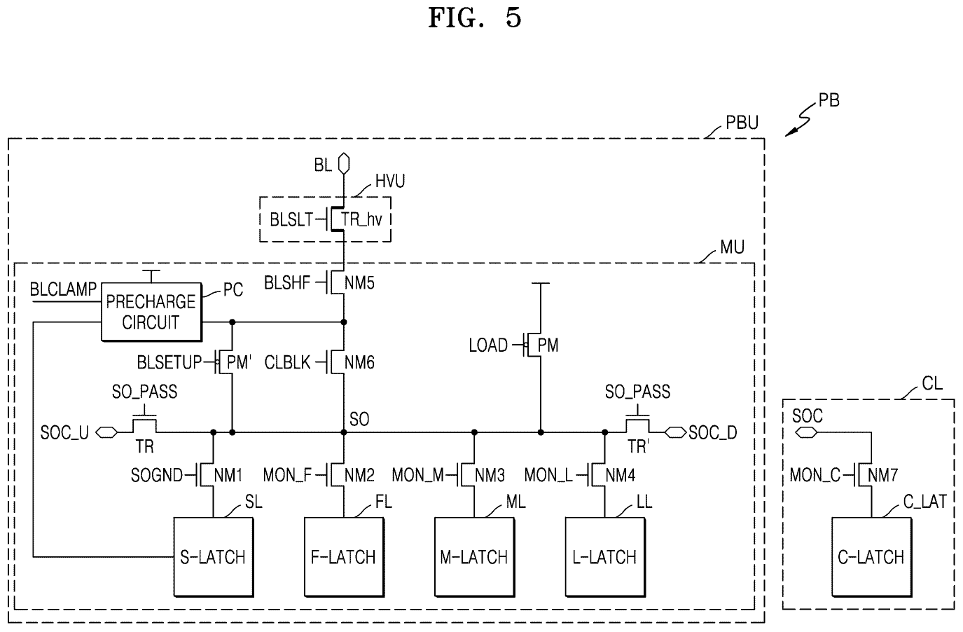

FIG. 5 is a circuit diagram illustrating in detail an example of a page buffer PB.

Referring to FIG. 5, the page buffer PB may include a page buffer unit PBU and a cache latch CL, and the cache latch CL may include a latch C_LAT. The page buffer PB may correspond to an implementation example of the page buffer PB of FIG. 4. The page buffer unit PBU may include a main unit MU. The page buffer unit PBU may further include a bit line selection transistor TR_hv which is connected to a bit line BL and is driven by a bit line selection signal BLSLT. The bit line selection transistor TR_hv may be implemented as a high voltage transistor and may be disposed in a well region (i.e., a high voltage unit HVU) which differs from the main unit MU.

The main unit MU may include a sensing latch SL, a force latch FL, an upper bit latch ML, and a lower bit latch LL. The main latch M_LAT of FIG. 4 may correspond to the sensing latch SL, the force latch FL, the upper bit latch ML, or the lower bit latch LL. A transistor NM1 may be connected between the sensing node SO and the sensing latch SL and may be driven by a ground control signal SOGND. A transistor NM2 may be connected between the sensing node SO and the force latch FL and may be driven by a force monitoring signal MON_F. A transistor NM3 may be connected between the sensing node SO and the upper bit latch BL and may be driven by an upper bit monitoring signal MON_M. A transistor NM4 may be connected between the sensing node SO and the lower bit latch LL and may be driven by a lower bit monitoring signal MON_L.

In a read or program verify operation, the sensing latch SL may store data stored in a memory cell or a sensing result of a threshold voltage of the memory cell. Also, in a program operation, the sensing latch SL may be used to apply a program bit line voltage or a program inhibit voltage to the bit line BL. The force latch FL may be used to store force data and improve a threshold voltage distribution in a program operation. The upper bit latch ML, the lower bit latch LL, and the cache latch CL may be used to store data input from the outside in a program operation. The cache latch CL may receive, through the sensing line SL, data read from a memory cell in a read operation and may output the received data to the outside through the data I/O line.

The precharge circuit PC may control a precharge operation on the bit line BL or the sensing node SO, based on a bit line clamping control signal BLCLAMP. A transistor PM′ may be driven by a bit line setup signal BLSETUP, a transistor NM5 may be driven by the bit line setup signal BLSETUP, and a transistor NM6 may be driven by a bit line connection control signal CLBLK. The precharge transistor PM may be connected to the sensing node SO and may be driven by the load signal LOAD to precharge the sensing node SO in a precharge period.

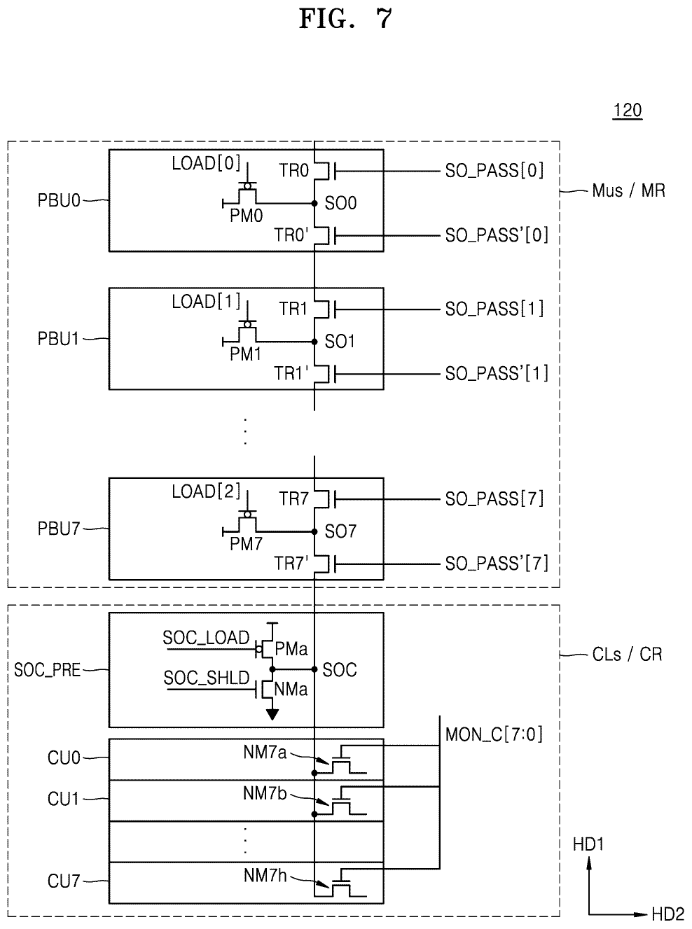

The main unit MU may further include a pair of pass transistors (i.e., first and second pass transistors TR and TR′) connected to the sensing node SO. The first and second pass transistors TR and TR′ may be driven based on a pass control signal SO_PASS. The first pass transistor TR may be connected between a first terminal SOC_U and the sensing node SO, and the second pass transistor TR′ may be connected between a second terminal SOC_D and the sensing node SO. For example, when the page buffer unit PBU is a second page buffer unit PBU1 of FIG. 7, the first terminal SOC_U may be connected to one end of a pass transistor included in the first page buffer unit PBU0, and the second terminal SOC_D may be connected to one end of a pass transistor included in a third page buffer unit. Accordingly, the sensing node SO may be electrically connected to a combined sensing node SOC through pass transistors included in each of third to nth+1 page buffer units.

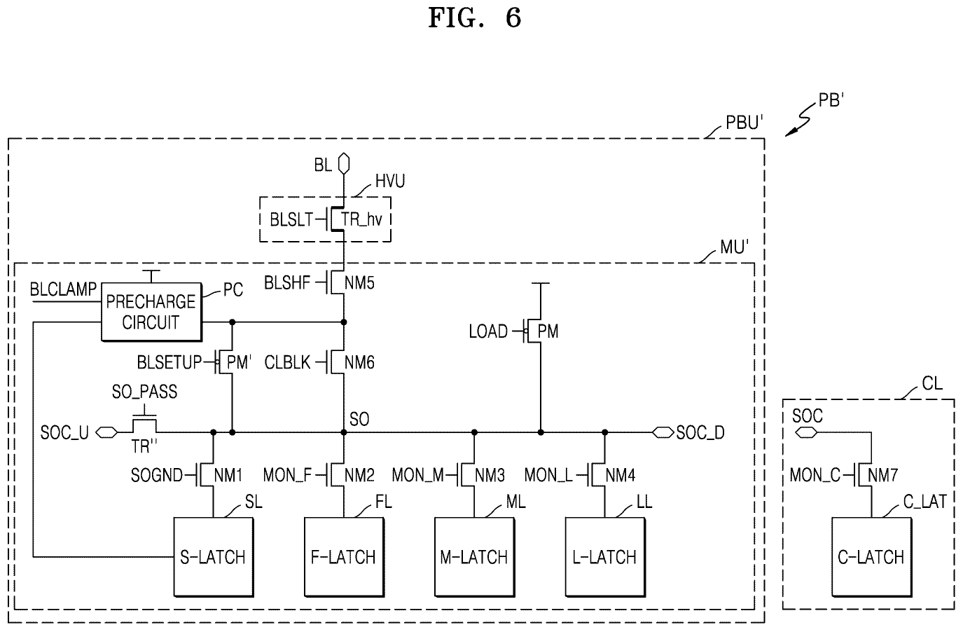

FIG. 6 is a circuit diagram illustrating in detail an example of a page buffer PB′.

Referring to FIG. 6, the page buffer PB′ may include a page buffer unit PBU′ and a cache unit CU, and the page buffer unit PBU′ may include a main unit MU′ and a high voltage unit HVU. The page buffer PB′ may correspond to an implementation example of the page buffer PB of FIG. 5.

The page buffer unit PBU of FIG. 5 may include the first and second pass transistors TR and TR′, and the page buffer unit PBU′ may include one pass transistor TR″.

The pass transistor TR″ may be driven based on a pass control signal SO_PASS and may be connected between a first terminal SOC_U and a second terminal SOC_D. For example, a source of the pass transistor TR″ may be connected to the first terminal SOC_U, and a drain of the pass transistor TR″ may be connected to a sensing node SO and the second terminal SOC_D.

However, the present disclosure is not limited thereto, and the source of the pass transistor TR″ may be connected to the first terminal SOC_U and the sensing node SO, and the drain of the pass transistor TR″ may be connected to the second terminal SOC_D.

FIG. 7 illustrates a multi-stage structure of an example of a page buffer circuit 120.

Referring to FIG. 7, the page buffer circuit 120 may include first to eighth page buffer units PBU0 to PBU7 and first to eighth cache latches CL0 to CL7. Each of the first to eighth page buffer units PBU0 to PBU7 may include at least one pass transistor, and the pass transistors may be driven by a pass control signal SO_PASS[7:0]. Also, the first page buffer unit PBU0 may further include a plurality of transistors (for example, first to sixth transistors NM1 to NM6 and transistors included in the sensing latch SL, the force latch FL, the upper bit latch MBL, and the lower bit latch LBL of FIG. 6) arranged in a first horizontal direction HD1, between a first pass transistor TR0 and a second pass transistor TR0′.

In some implementations, each of the first to eighth page buffer units PBU0 to PBU7 may include one pass transistor, and for example, the first page buffer unit PBU0 may include the first pass transistor TR0 connected to a first sensing node SO0, the second page buffer unit PBU1 may include the second pass transistor TR1 connected to a second sensing node SO1, and the eighth page buffer unit PBU7 may include the eighth pass transistor TR7 connected to an eighth sensing node SO7. When the pass control signal SO_PASS[7:0] is activated, the first to eighth pass transistors TR0 to TR7 may be turned on, and thus, the first to eighth pass transistors TR0 to TR7 may be serially connected to one another, and the first to eighth sensing nodes SO0 to SO7 may be connected to one another.

Referring to FIG. 7, each of the first to eighth page buffer units PBU0 to PBU7 may include two pass transistors. Therefore, the page buffer circuit 120 may include sixteen pass transistors TR0, TR0′ to TR7, and TR7′, and the sixteen pass transistors TR0, TR′ to TR7, and TR7′ may be serially connected to one another. For example, the first page buffer unit PBU0 may include first and second pass transistors TR0 and TR0′ which are serially connected to each other. For example, the first and second pass transistors TR0 and TR0′ may be implemented as NMOS transistors, but the present disclosure is not limited thereto.

A source of the first pass transistor TR0 may be connected a first terminal (for example, SOC_U of FIG. 6), and a drain of the first pass transistor TR0 may be connected to the first sensing node SO0. The pass control signal SO_PASS[7:0] may be applied to a gate of the first pass transistor TR0.

A source of the second pass transistor TR0′ may be connected to the first sensing node SO0, and a drain of the second pass transistor TR0′ may be connected to a second terminal (for example, SOC_D of FIG. 6). The pass control signal SO_PASS′[7:0] may be applied to a gate of the second pass transistor TR0′.

The second page buffer unit PBU1 may include first and second pass transistors TR1 and TR1′ which are serially connected to each other. A pass control signal SO_PASS[1] and a pass control signal SO_PASS′[1] may be applied to gates of the first and second pass transistors TR1 and TR1′.

The eighth page buffer unit PBU7 may include first and second pass transistors TR7 and TR7′ which are serially connected to each other. A pass control signal SO_PASS[7] and a pass control signal SO_PASS′[7] may be applied to gates of the first and second pass transistors TR7 and TR7′.

As illustrated in FIG. 7, different pass control signals may be applied to gates of two pass transistors included in one page buffer unit. However, the present disclosure is not limited thereto, and in some implementations, the same pass control signal may be applied to gates of pass transistors (for example, TR0′ and TR1′) disposed between adjacent sensing nodes (for example, SO0 and SO1). That is, the same pass control signal may be applied to gates of pass transistors (for example, TR0′ and TR1′) disposed between adjacent sensing nodes (for example, SO0 and SO1), and thus, the adjacent sensing nodes (for example, SO0 and SO1) may be selectively connected to each other.

A first cache unit CU0 may include a monitor transistor NM7a. For example, the monitor transistor NM7a may correspond to the transistor NM7 of FIG. 6. A source of the monitor transistor NM7a may be connected to a combined sensing node SOC, and a cache monitoring signal MON_C[7:0] may be applied to a gate of the monitor transistor NM7a. Although not shown, the first cache unit CU0 may further include a plurality of transistors (for example, a plurality of transistors included in the latch C_LAT of FIG. 6) arranged in a first horizontal direction HD1. Each of second to eighth cache units CU1 to CU7 may have substantially the same configuration as that of the first cache unit CU0. Monitor transistors NM7a to NM7h respectively included in the first to eighth cache units CU0 to CU7 may be connected to the combined sensing node SOC in parallel and in common. In detail, a source of each of the monitor transistors NM7a to NM7h may be connected to the combined sensing node SOC in common.

In some implementations, when first and second pass control signals SO_PASS[0] to SO_PASS[7] and SO_PASS′[0] to SO_PASS′[7] are activated, first and second pass transistors TR0 to TR7 and TR0′ to TR7′ may be turned on. Therefore, the first and second pass transistors TR0 to TR7′ included in each of the first to eighth page buffer units PBU0 to PBU7 may be serially connected to one another, and all of the first to eighth sensing nodes SO0 to SO7 may be electrically connected to the combined sensing node SOC.

The first to eighth page buffer units PBU0 to PBU7 may further include precharge transistors PM0 to PM7, respectively. Each of the precharge transistors PM0 to PM7 may include a gate to which a load signal LOAD[7:0] is applied. Each of the precharge transistors PM0 to PM7 may precharge a corresponding sensing node at a precharge voltage PBIVC level, in response to the load signal LOAD[7:0].

For example, referring to FIG. 7, in the first page buffer unit PBU0, the precharge transistor PMO may be connected between the first sensing node SO0 and a voltage terminal to which the precharge voltage PBIVC (for example, VDD) level is applied and may include a gate to which a load signal LOAD[0] is applied. The precharge transistor PM0 may precharge the first sensing node SO0 at the precharge voltage PBIVC level, in response to the load signal LOAD[0].

The page buffer circuit 120 may further include a precharge circuit SOC_PRE between the eighth page buffer unit PBU7 and the first cache unit CU0. Referring to FIG. 7, cache latches CLs may further include the precharge circuit SOC_PRE.

The precharge circuit SOC_PRE may include a shielding transistor NMa and a precharge transistor PMa for precharging the combined sensing node SOC. The precharge transistor PMa may be driven by a combined sensing node load signal SOC_LOAD, and when the precharge transistor PMa is turned on, the combined sensing node SOC may be precharged at the precharge voltage PBIVC level. The shielding transistor NMa may be driven by a combined sensing node shielding signal SOC_SHLD, and when the shielding transistor NMa is turned on, the combined sensing node SOC may be discharged at a ground level.

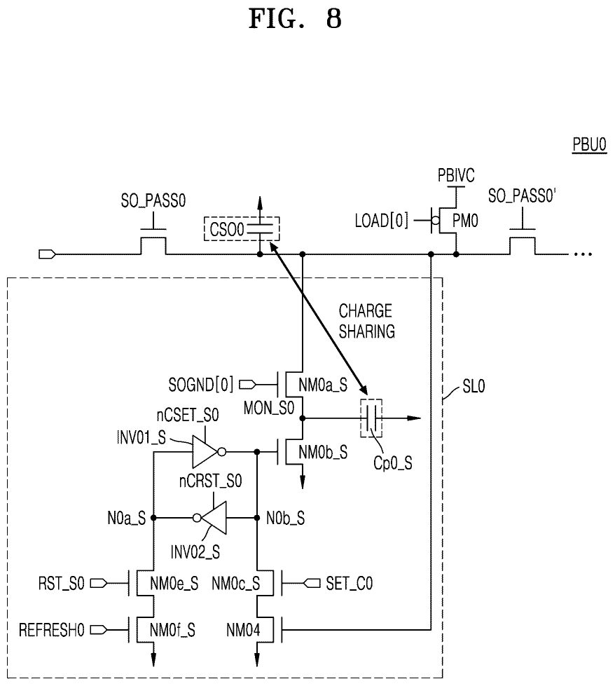

FIG. 8 is a circuit diagram illustrating in detail an example of a sensing latch SL. A first sensing latch SL0 of FIG. 8 may correspond to an implementation example of the sensing latch SL described above with reference to FIG. 5.

Also, the page buffer units may have the same configuration. Hereinafter, therefore, a configuration of a first page buffer unit PBU0 illustrated in FIG. 8 will be described.

Referring to FIG. 8, the first page buffer unit PBU0 may include a first sensing latch SL0. Here, the first sensing latch SL0 may correspond to the main latch M_LAT described above with reference to FIG. 4. That is, the first sensing latch SL0 of FIG. 8 may correspond to an implementation example of the main latch M_LAT described above with reference to FIG. 4.

In FIG. 8, only the first sensing latch SL0 is illustrated, but according to implementations, the first page buffer unit PBU0 may further include a first force latch, a first upper bit latch, or a first lower bit latch. Also, the first force latch, the first upper bit latch, or the first lower bit latch may be implemented in the same structure as that of the first sensing latch SL0.

That is, the force latch FL, the upper bit latch ML, or the lower bit latch LL described above with reference to FIG. 5 may be implemented in the same structure as that of the first sensing latch SL0.

Referring to FIG. 8, the first page buffer unit PBU0 may further include a capacitor CSO0. Here, the capacitor CSO0 may be connected to the first sensing node SO0.

Referring to FIGS. 5 and 8, a page buffer unit PBU may include a corresponding capacitor CSO so as to stably perform a read operation or a program operation of the page buffer unit PBU. That is, each of page buffer units may include a corresponding capacitor CSO. For example, the first page buffer unit PBU0 may include a capacitor CSO0 connected to the first sensing node SO0, and the second page buffer unit PBU1 may include a capacitor CSO1 connected to the second sensing node SO1.

Also, for example, a corresponding capacitor CSO may reduce voltage fluctuation corresponding to data in the sensing node SO or may stabilize a signal corresponding to the data, and thus, the page buffer unit PBU may more accurately read data of a memory cell. Also, the corresponding capacitor CSO may hold a voltage corresponding to data read from the memory cell, and thus, the page buffer unit PBU may prevent a corresponding voltage from being rapidly reduced when processing corresponding data. Also, the corresponding capacitor CSO may perform a function of a noise filter and may thus protect corresponding data from external interference or internal switching noise, thereby enabling reliable data processing of the page buffer unit PBU. Also, the corresponding capacitor CSO may improve a timing characteristic of a corresponding circuit. Here, the capacitor CSO may be referred to as a sensing node precharging capacitor.

Referring to FIG. 8, the first sensing latch SL0 may include a transistor NM0a, a transistor NM0b, a transistor NM0c, a transistor NM0d, a transistor NM0e, a transistor NM0f, an inverter INV01_S, and an inverter INV02_S.

Also, the first sensing latch SL0 may further include a parasitic capacitor Cp0_S. Here, a parasitic capacitance caused by a junction of a transistor NM0a_S and a transistor NM0b_S may occur. That is, each of main latches may include a parasitic capacitor corresponding to the parasitic capacitance described above.

Referring to FIG. 8, the first page buffer unit PBU0 is illustrated as including a parasitic capacitor Cp0_S corresponding to the parasitic capacitance described above.

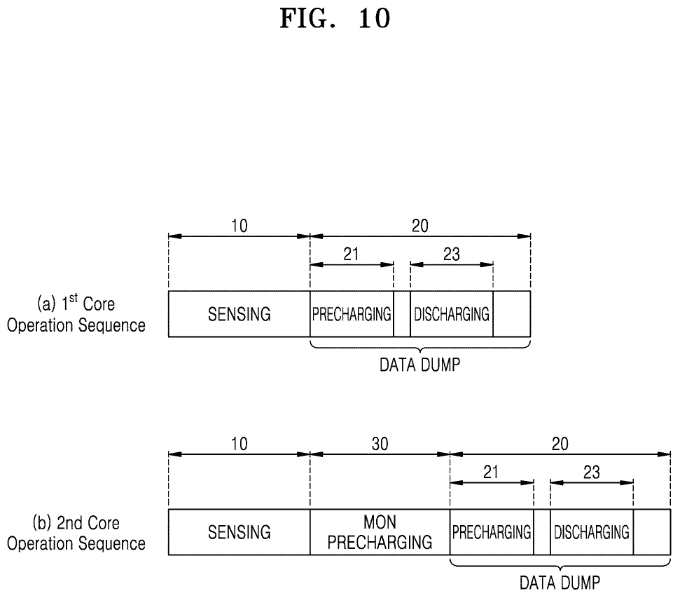

Furthermore, a precharge voltage PBIVC level may be applied to the first sensing node SO0 as the precharge transistor PM0 is activated by a load signal LOAD[0], and then, despite deactivation of the precharge transistor PM0, the first sensing node SO0 may maintain the precharge voltage PBIVC level based on the capacitor CSO0. However, due to the parasitic capacitance described above, charge sharing may occur between the capacitor CSO0 and the parasitic capacitor Cp0_S to cause the undesired drop of a voltage level. In some implementations, the undesired drop of a voltage level of the sensing node SO (for example, the first sensing node SO0) may be prevented based on a first core operation sequence or a second core operation sequence to be described below. This will be described below with reference to FIGS. 10 to 20.

Here, a precharge voltage (a precharge bit line voltage control (PBIVC)) may represent a voltage applied to the sensing node SO so as to prepare a next read operation or a next program operation.

A source terminal of the transistor NM0a_S may be connected to the first sensing node SOO, a drain terminal of the transistor NM0a_S may be connected to a node MON, and a gate terminal of the transistor NMOa_S may be connected to a ground control signal SOGND line. That is, the transistor NM0a_S may be driven by a ground control signal SOGND. Here, the transistor NM0a_S may be referred to as an enable transistor.

The transistor NM0a_S may correspond to one of the transistors NM1 to NM4 described above with reference to FIG. 5. Also, the ground control signal SOGND may correspond to one of a monitoring signal MON_F, an upper bit monitoring signal MON_M, and a lower bit monitoring signal MON_L, based on the kind of main latch M_LAT. For example, in a case where the force latch FL is implemented in a structure illustrated in FIG. 8, the transistor NM0a_S may correspond to the transistor NM2 described above with reference to FIG. 5, and the ground control signal SOGND may correspond to the monitoring signal MON_F described above with reference to FIG. 5.

A source terminal of the transistor NM0b_S may be connected to the node MON_S0, and a gate terminal of the transistor NM0a_S may be connected to a node N0b_S. That is, the transistor NM0b_S may be driven by a voltage level of the node N0b_S. Here, the transistor NM0b_S may be referred to as a monitoring transistor.

Here, the transistor NM0a_S and the transistor NM0b_S may be turned on, and thus, the first sensing node SO0 may be discharged.

The inverter INV01_S and the inverter INV02_S may be cross-coupled to each other. Referring to FIG. 8, an output terminal of the inverter INV01_S may be connected to the node N0b_S, and an input terminal of the inverter INV01_S may be connected to the node N0a_S. Also, an output terminal of the inverter INV02_S may be connected to the node N0b_S, and an output terminal of the inverter INV02_S may be connected to the node N0a_S.

Also, the inverter INV01_S may be enabled in response to a set control signal nCSET_S0, and thus, the inverter INV01_S may perform an inverting operation based on the set control signal nCSET_S0. Likewise, the inverter INV02_S may be enabled in response to a reset control signal nCRST_S0, and thus, the inverter INV01_S may perform an inverting operation based on the reset control signal nCRST_S0.

A source terminal of the transistor NM0c_S may be connected to the node N0b_S, and a gate terminal of the transistor NM0c_S may be connected to a set signal SET_S0 line. That is, the transistor NM0c_S may be driven by a set signal SET_S0.

A source terminal of the transistor NM0d_S may be connected to a drain terminal of the transistor NM0c_S, and a gate terminal of the transistor NM0d_S may be connected to the first sensing node SO0. That is, the transistor NM0c_S may be driven by a voltage level of the first sensing node SO0.

Here, the transistor NM0c_S and the transistor NM0d_S may be turned on, and thus, the node N0b_S may be discharged.

A source terminal of the transistor NM0e_S may be connected to the node N0a_S, and a gate terminal of the transistor NM0e_S may be connected to a reset signal RST_S0 line. That is, the transistor NM0e_S may be driven by a reset signal RST_S0.

A source terminal of the transistor NM0f_S may be connected to a drain terminal of the transistor NM0e_S, and a gate terminal of the transistor NM0f_S may be connected to a refresh signal RFRESH0 line. That is, the transistor NM0f_S may be driven by a refresh signal RFRESH0.

Here, the transistor NM0e_S and the transistor NM0f_S may be turned on, and thus, the node N0a_S may be discharged.

Furthermore, the first to eighth page buffer units PBU0 to PBU7 may be disposed in a main region MR, the first to eighth cache units CU0 to CU7 may be disposed in a cache region CR, and the main region MR and the cache region CR may be adjacent to each other in the first horizontal direction HD1.

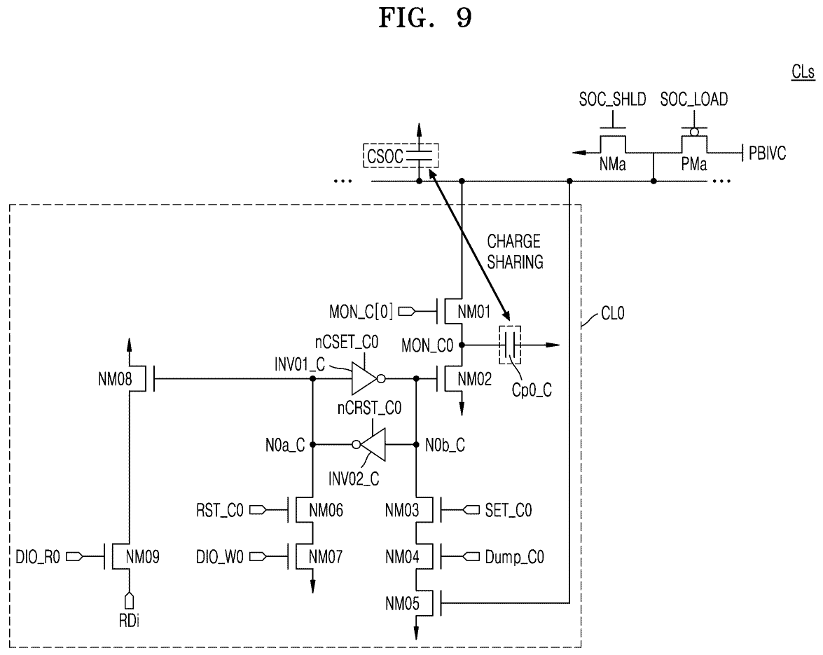

FIG. 9 is a circuit diagram illustrating in detail an example of a main latch M_LAT. Here, the first cache latch CL0 of FIG. 9 may correspond to an implementation example of the cache latch CL of FIG. 4.

Referring to FIG. 9 in conjunction with FIG. 7, cache latches CLs may further include a capacitor CSOC. Here, the capacitor CSOC may be connected to a combined sensing node SOC.

The cache latches CLs may include the capacitor CSOC, so as to stably perform a read operation or a program operation of each of the cache latches CLs. Here, the capacitor CSOC may be referred to as a combined sensing node precharging capacitor.

For example, the capacitor CSOC may reduce voltage fluctuation corresponding to data in the combined sensing node SOC or may stabilize a signal corresponding to the data, and thus, may allow data corresponding to the combined sensing node SOC to be stably maintained. Also, as the sensing node SO is connected to the combined sensing node SOC, the capacitor CSOC may hold a voltage corresponding to data read from a memory cell. Also, the capacitor CSOC may perform a function of a noise filter and may thus decrease external interference or internal switching noise. Also, the capacitor CSOC may improve a timing characteristic of a corresponding circuit.

The precharge transistor PMa may be driven by a combined sensing node load signal SOC_LOAD, and when the precharge transistor PMa is turned on, the combined sensing node SOC may be precharged at the precharge voltage PBIVC level. The shielding transistor NMa may be driven by a combined sensing node shielding signal SOC_SHLD, and when the shielding transistor NMa is turned on, the combined sensing node SOC may be discharged at a ground level.

Referring to FIG. 9, the first cache latch CL0 may include a transistor NM01, a transistor NM02, a transistor NM03, a transistor NM04, a transistor NM05, a transistor NM06, a transistor NM07, a transistor NM08, a transistor NM09, an inverter INV01_C, and an inverter INV02_C.

Also, the first cache latch CL0 may further include a parasitic capacitor Cp0_C. Here, a parasitic capacitance caused by a junction of the transistor NM01 and the transistor NM02 may occur. That is, each of cache latches CLs may include a parasitic capacitor corresponding to the parasitic capacitance described above.

Referring to FIG. 9, the first cache latch CL0 is illustrated as including a parasitic capacitor Cp0_C corresponding to the parasitic capacitance described above.

Furthermore, a precharge voltage PBIVC level may be applied to the combined sensing node SOC as the precharge transistor PMa is activated by a combined sensing node load signal SOC_LOAD, and then, despite deactivation of the precharge transistor PMa, the combined sensing node SOC may maintain the precharge voltage PBIVC level based on the capacitor CSOC. However, due to the parasitic capacitance described above, charge sharing may occur between the capacitor CSOC and the parasitic capacitor Cp0_C to cause the undesired drop of a voltage level. In some implementations, the undesired drop of a voltage level of the combined sensing node SOC may be prevented based on a first core operation sequence or a second core operation sequence to be described below. This will be described below with reference to FIGS. 10 to 20.

A source terminal of the transistor NM01 may be connected to the combined sensing node SOC, a drain terminal of the transistor NM01 may be connected to a node MON_C, and a gate terminal of the transistor NM01 may be connected to a cache monitoring signal MON_C line. That is, the transistor NM01 may be driven by a cache monitoring signal MON_C. Here, the transistor NM01 may be referred to as an enable transistor. Also, the transistor NM01 may correspond to the transistor NM7 described above with reference to FIG. 5 or 6.

A source terminal of the transistor NM02 may be connected to the node MON_C, and a gate terminal of the transistor NM02 may be connected to a node NC. That is, the transistor NM02 may be driven by a voltage level of the node NC. Here, the transistor NM02 may be referred to as a monitoring transistor.

Here, the transistor NM01 and the transistor NM02 may be turned on, and thus, the combined sensing node SOC may be discharged.

The inverter INV01_C and the inverter INV02_C may be cross-coupled to each other. Referring to FIG. 9, an output terminal of the inverter INV01_C may be connected to a node N0b_C, and an input terminal of the inverter INV01_C may be connected to the node N0b_C. Also, an output terminal of the inverter INV02_C may be connected to the node N0b_C, and an output terminal of the inverter INV02_C may be connected to the node N0a_C.

Also, the inverter INV01_C may be enabled in response to a set control signal nCSET_C0, and thus, the inverter INV01_C may perform an inverting operation based on the set control signal nCSET_C0. Likewise, the inverter INV02_C may be enabled in response to a reset control signal nCRST_C0, and thus, the inverter INV02_C may perform an inverting operation based on the reset control signal nCRST_C0. Here, in some implementations, the set control signal nCSET_C0 and the reset control signal nCRST_C0 may differ from the set control signal nCSET_S0 and the reset control signal nCRST_S0 each described above with reference to FIG. 8.

A source terminal of the transistor NM03 may be connected to the node N0b_C, and a gate terminal of the transistor NM03 may be connected to a set signal SET C0 line. That is, the transistor NM06 may be driven by a set signal SET_C0.

A source terminal of the transistor NM04 may be connected to a drain terminal of the transistor NM03, and a gate terminal of the transistor NM04 may be connected to a dump signal Dump_C0 line. That is, the transistor NM04 may be driven by a dump signal Dump_C0.

A source terminal of the transistor NM05 may be connected to a drain terminal of the transistor NM04, and a gate terminal of the transistor NM05 may be connected to the combined sensing node SOC. That is, the transistor NM05 may be driven by a voltage level of the combined sensing node SOC.

Here, the transistor NM03, the transistor NM04, and the transistor NM05 may be turned on, and thus, the node N0b_C may be discharged.

A source terminal of the transistor NM06 may be connected to the node N0a_C, and a gate terminal of the transistor NM06 may be connected to a reset signal RST_C0 line. That is, the transistor NM06 may be driven by a reset signal RST_C0.

A source terminal of the transistor NM07 may be connected to a drain terminal of the transistor NM06, and a gate terminal of the transistor NM07 may be connected to a write control signal DIO_WO line. That is, the transistor NM06 may be driven by a write control signal DIO_WO.

Here, the transistor NM06 and the transistor NM07 may be turned on, and thus, the node N0a_C may be discharged.

The first cache latch CLO may be connected to an I/O terminal RDi through the transistor NM08 and the transistor NM09.

The transistor NM08 may include a gate connected to the node N0a_C, and the transistor NM08 may be turned on or off based on a voltage level of the node N0a_C.

The transistor NM09 may be driven by a read control signal DIO_RO. When the transistor NM09 is turned on as the read control signal DIO_RO is activated, a voltage level of the I/O terminal RDi may be determined to be 1 or 0 based on a voltage level of the node N0a_C.

FIGS. 10(a) and (b) is a diagram illustrating an example of a core operation sequence. Here, the core operation sequence may denote an operation sequence of a page buffer PB.

Referring to FIG. 10 in conjunction with FIG. 4, in the page buffer PB, a core operation sequence may correspond to one of a first core operation sequence and a second core operation sequence.

First, the first core operation sequence may be described with reference to FIG. 10(a).

Referring to FIG. 10(a), the first core operation sequence may include a data sensing period 10 where a data sensing operation is performed and a data dumping period 20 where a data dumping operation (or a data transfer operation) is performed.

Referring to FIG. 10(a) in conjunction with FIG. 4, in the data sensing period 10, a pass control signal SO_PASS may be deactivated, and a pass transistor TR may be turned off. Therefore, the page buffer unit PBU may not be electrically connected to a combined sensing node SOC, and the page buffer unit PBU may not be electrically connected to a cache latch CL. Also, the page buffer unit PBU may not be electrically connected to an adjacent page buffer unit.

Moreover, the data sensing period 10 may include a precharge period where a voltage of a sensing node SO or a bit line BL is precharged at a precharge voltage PBIVC level, a develop period where the bit line BL is electrically connected to the sensing node SO to develop the voltage of the sensing node SO, and a sensing period where the voltage of the sensing node SO is sensed.

Also, in a case which transfers data from a cache latch CL to a main latch M_LAT, or a case which transfers data from the main latch M_LAT to another main latch, the data sensing period 10 may be omitted in the first core operation sequence and the second core operation sequence.

Referring to FIG. 10(a) in conjunction with FIG. 4, in the data dumping period 20, a pass control signal SO_PASS may be activated, and a pass transistor TR may be turned on. Therefore, the page buffer unit PBU may be electrically connected to the combined sensing node SOC, and the page buffer unit PBU may be electrically connected to the cache latch CL. Also, the page buffer unit PBU may be electrically connected to an adjacent page buffer unit.

For example, the data dumping period 20 may include a period where an operation of dumping read data, stored in the main latch M_LAT, into the cache latch CL is performed, and a period where an operation of dumping program data, stored in the cache latch CL, into the main latch M_LAT is performed, or a period which transfers the data, stored in the cache latch CL, to a data I/O circuit.

Also, with time, the data dumping period 20 may include a precharging period 21 which precharges the sensing node SO or the combined sensing node SOC and a discharging period 23 which discharges the sensing node SO or the combined sensing node SOC.

The data dumping period 20 may denote a period where the main latch M_LAT or the cache latch CL transfers data to another latch (main latch M_LAT or cache latch CL).

For example, the data dumping period 20 may correspond to an operation of dumping the read data, stored in the main latch M_LAT, into the cache latch CL, or dumping data between main latches M_LAT, or dumping data from a main latch, included in a corresponding page buffer unit, into a main latch included in another page buffer unit, or dumping data between main latches included in one page buffer unit, or dumping the program data, stored in the cache latch CL, to the main latch M_LAT.

At this time, a precharging operation and a discharging operation may be performed on a corresponding combined sensing node or a corresponding sensing node connected to the main latch M-LAT or the cache latch CL. That is, the data dumping period may include a precharging period 21 where a sensing node or a combined sensing node is precharged and a discharging period 23 where the sensing node or the combined sensing node is discharged. Also, although not shown in FIG. 10, the data dumping period 20 may further include an SO sensing period.

For example, in a case which dumps data from a latch, storing the data, into a target latch to which the data is to be transferred, a sensing node or a combined sensing node connected to the latch storing the data may be discharged and precharged. Subsequently, a sensing node or a combined sensing node connected to the target latch may be developed by activating a set signal to a reset signal in the target latch, and thus, a voltage level and a reference voltage level of the sensing node or the combined sensing node connected to the target latch may be compared with each other, and the target latch may store data based on a comparison result.

Furthermore, referring to FIGS. 8 and 10, only the first sensing latch SL0 is illustrated in FIG. 8, but a force latch FL, an upper bit latch ML, or a lower bit latch LL may be implemented in the same structure as that of the first sensing latch SL0. That is, the main latch M_LAT may have a parasitic capacitance (for example, a parasitic capacitance Cp0_S (see FIG. 8)) caused by a junction between an enable transistor (transistor NM0a_S (see FIG. 8)) and a monitoring transistor (transistor NM0b_S (see FIG. 8)), and charge sharing between a capacitor (for example, a capacitor CSO0 (see FIG. 8)) connected to a corresponding sensing node and a capacitor (for example, a parasitic capacitor Cp0_S (see FIG. 8)) corresponding to the parasitic capacitance described above may occur in the main latch M_LAT. Therefore, a voltage level which is precharged in a corresponding sensing node in the precharging period 21 may be lowered more than a precharging voltage PBIVC level.

Referring to FIGS. 9 and 10, an arbitrary cache latch CL connected to the combined sensing node SOC may be implemented in the same structure as that of the first cache latch CL0 of FIG. 9. The cache latch CL may have a parasitic capacitance (a parasitic capacitance Cp0_C) caused by a junction between an enable transistor (transistor NM01 (see FIG. 9)) and a monitoring transistor (transistor NM02 (see FIG. 9)), and charge sharing between a capacitor CSO0 connected to a combined sensing node and a parasitic capacitor (for example, a parasitic capacitor Cp0_C (see FIG. 9)) corresponding to the parasitic capacitance described above may occur in the cache latch CL. Therefore, a voltage level which is precharged in the combined sensing node SOC in the precharging period 21 may be lowered more than the precharging voltage PBIVC level.

To increase a voltage level precharged in the sensing node SO or the combined sensing node SOC (i.e., to prevent the drop of voltage level caused by a parasitic capacitance), the page buffer PB may operate in the second core operation sequence. In some implementations, a voltage level precharged in the sensing node SO or the combined sensing node SOC may increase in the precharging period 21, and thus, a sensing margin may increase.

Referring to FIG. 10(b), comparing with the first core operation sequence, the second core operation sequence may further include an MON precharging period 30 between the data sensing period 10 and the data dumping period 20.

Here, in a case which transfers data from a cache latch CL to a main latch M_LAT, or a case which transfers data from the main latch M_LAT to another main latch, the data sensing period 10 may be omitted in the first core operation sequence and the second core operation sequence.

That is, the second core operation sequence may include the MON precharging period 30 before a precharging period 21 of the data dumping period 20.

The MON precharging period 30 may represent a period where a node (for example, a node MON_S0 of FIG. 8) connecting an enable transistor (for example, a transistor NM0a_S or a transistor NM01 of FIG. 9) to a monitoring transistor (for example, a transistor NM0b_S or a transistor NM02 of FIG. 9) is precharged.

Here, the enable transistor may denote a transistor (for example, a transistor NM0a_S of FIG. 8) which is included in the main latch M_LAT, directly connected to the sensing node SO, and driven by a monitoring signal, or may denote a transistor (for example, a transistor NM01 of FIG. 9) which is included in the cache latch CL, directly connected to the combined sensing node SOC, and driven by a cache monitoring signal.

Also, the monitoring transistor may denote a transistor (for example, a transistor NM0b_S of FIG. 8 or a transistor NM02 of FIG. 9) which is connected to the enable transistor and is driven by a voltage level of a node latching data in a latch circuit (for example, cross-coupled inverters).

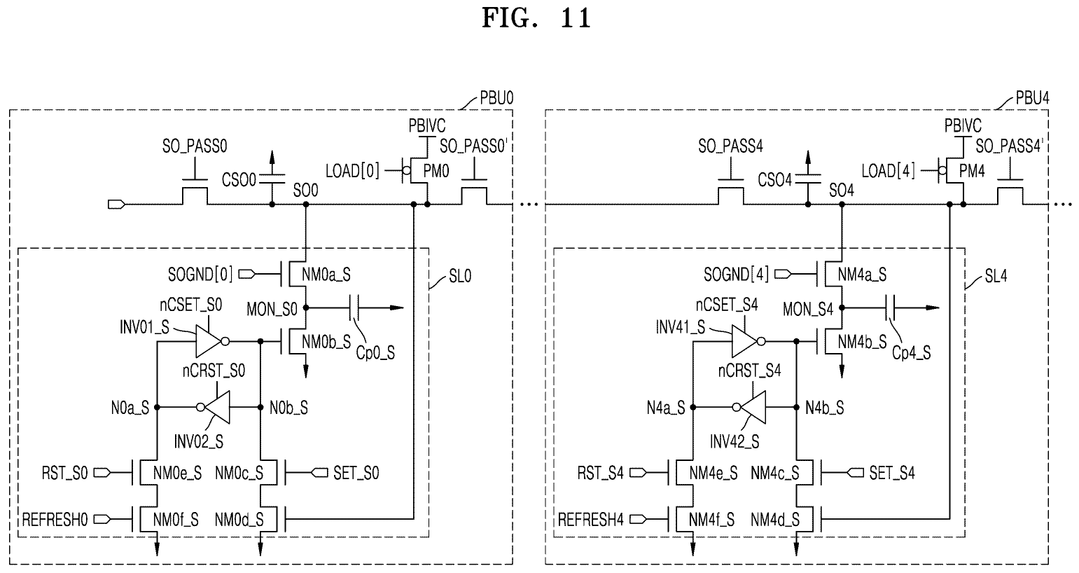

Hereinafter, the second core operation sequence will be described in detail with reference to FIGS. 11 to 15.

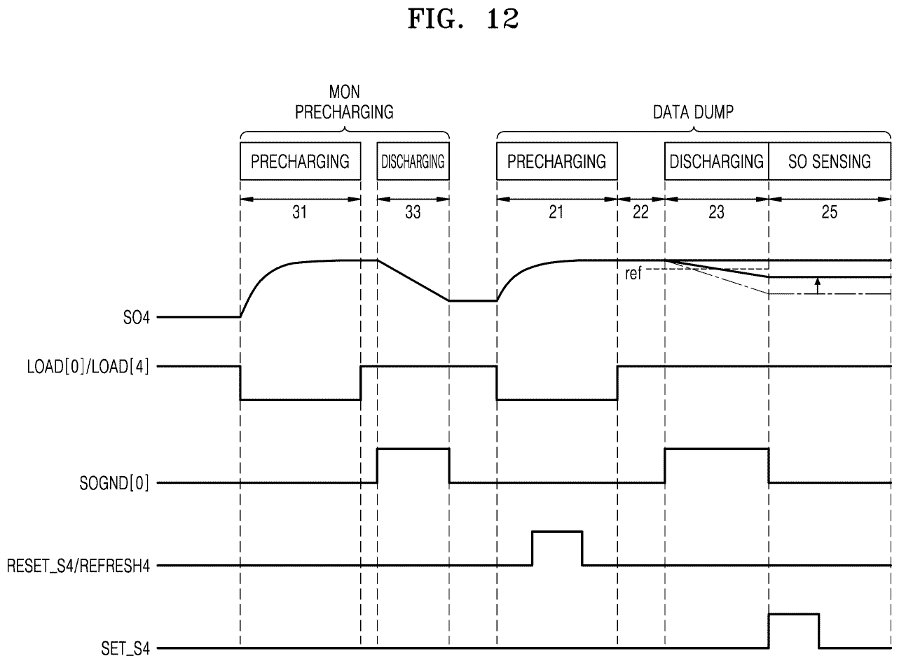

FIG. 11 is a circuit diagram describing an example of a data dumping operation between main latches. FIG. 12 is a timing diagram of an example of a data dumping operation between main latches.

In detail, a data dumping operation between a first cache latch CL0 included in a first page buffer unit PBU0 and a fifth cache latch CL4 included in a fifth page buffer unit PBU4 may be described with reference to FIGS. 11 and 12.

Referring to FIG. 11, the fifth page buffer unit PBU4 may have the same structure as that of the first page buffer unit PBU0 of FIG. 9. For example, the fifth page buffer unit PBU4 may further include a fifth force latch, a fifth upper bit latch, or a fifth lower bit latch.

In a state where the first to fifth sensing nodes SO0 to SO4 are electrically connected to one another, a data dumping operation of transferring data of a first sensing latch SL0 to a fifth sensing latch SL4 may be performed. However, the present disclosure is not limited thereto, and the first sensing latch SL0 may correspond to an arbitrary main latch connected to a sensing node SO. Likewise, the fifth sensing latch SL4 may correspond to an arbitrary main latch connected to the sensing node SO.

For example, a first sensing latch SL0 may perform a data dumping operation on another main latch (for example, a first force latch, a first upper bit latch, or a first lower bit latch) included in the first page buffer unit PBU0. Also, the first sensing latch SL0 may perform a data dumping operation on a main latch (for example, the fifth force latch, the fifth upper bit latch, or the fifth lower bit latch) included in another page buffer unit sharing the sensing node SO instead of the first page buffer unit PBU0. Here, corresponding sensing nodes may be electrically connected to each other.

In FIGS. 11 and 12, a data dumping operation between a first sensing latch SL0 included in the first page buffer unit PBU0 and a fifth sensing latch SL4 included in the fifth page buffer unit PBU4 may be applied to the data dumping operations described above. Hereinafter, a data dumping operation between the first sensing latch SL0 and the fifth sensing latch SL4 will be described.

Here, first to fifth sensing nodes SO0 to SO4 may be electrically connected to one another. Referring to FIG. 7, a pass control signal SO_PASS[4:1] and a pass control signal SO_PASS′[4:1] may be activated. That is, the pass control signal SO_PASS[4:1] and the pass control signal SO_PASS′[4:1] may have a high level. In some implementations, a pass control signal SO_PASS′[4] may also have a high level.

Referring to FIG. 12, a data dumping period 20 may include a precharging period 21 where the sensing node SO is precharged, a time period 22, a discharging period 23 where the sensing node SO is discharged, and an SO sensing period 25 where the sensing node SO is sensed.

Here, the time period 22 may be a certain time period after the precharging period 21 and may be a transient time period for preparing a next operation (for example, the discharging period 23). In the time period 22, a load signal (for example, LOAD[0] or LOAD[4]) or a combined sensing node load signal SOC_LOAD may have a high level. Therefore, a precharging voltage PBIVC may not be applied to the combined sensing node SOC or the sensing node SO. Also, the time period 22 and the discharging period 23 may be referred to as an SO develop period, and the discharging period 23 may be referred to as an SO develop period.

Also, referring to FIG. 12, the second core operation sequence may include an MON precharging period 30 before the precharging period 21. The MON precharging period 30 may include a precharging period 31 where the sensing node SO is precharged and a discharging period 33 where the sensing node SO is discharged.

Also, referring to FIGS. 11 and 12, an example may be described where data sensed in the data sensing period 10 of FIG. 10 is stored in a node N0a_S of a first sensing latch SL0 before the MON precharging period 30.

Referring to FIGS. 11 and 12, in the precharging period 31, a load signal LOAD[0] and a load signal LOAD[4] may have a low level, a transistor PM0 may precharge the first sensing node SO0, and a transistor PM4 may precharge the fifth sensing node SO4. Although not shown in FIG. 11, in the precharging period 31, the second to fourth sensing nodes SO1 to SO3 may also be precharged by the transistors PM1 to PM3 based on a load signal LOAD[3:1] having a low level.

Referring to FIGS. 11 and 12, in the discharging period 33, the load signal LOAD[0] and the load signal LOAD[4] may have a high level, and a ground control signal SOGND[0] may have a high level. Therefore, a transistor NM0a_S may be turned on. As the transistor NM0a_S is turned on, a parasitic capacitor Cp0_S may be precharged. That is, as the parasitic capacitor Cp0_S is precharged, a node MON_S0 may be precharged.

Referring to FIGS. 11 and 12, in the precharging period 21, the load signal LOAD[0] and the load signal LOAD[4] may have a low level, the transistor PM0 may precharge the first sensing node SO0, and the transistor PM4 may precharge the fifth sensing node SO4. Although not shown in FIG. 11, in the precharging period 31, the second to fourth sensing nodes SO1 to SO3 may also be precharged by the transistors PM1 to PM3 based on a load signal LOAD[3:1] having a low level.

Also, in the precharging period 21, a reset signal RST_S4 and a refresh signal REFRESH4 may have a high level. Accordingly, a transistor NM4e_S and a transistor NM4f_S may be turned on, and thus, a node N4a_S may be discharged. That is, ‘0’ may be stored in the node N4a_S, and ‘1’ may be stored in a node N4b_S.

Referring to FIGS. 11 and 12, in the precharging period 23, the ground control signal SOGND[0] may have a high level. Therefore, the transistor NM0a_S may be turned on. When ‘0’ is stored in the node N0a_S, a transistor NM0b_S may be turned on, and thus, the first sensing node SO0 may be discharged. As described above, because the first to fifth sensing nodes SO0 to SO4 are electrically connected to one another, the first sensing node SO0 may be discharged, and thus, the fifth sensing node SO4 may be discharged. When ‘1’ is stored in the node N0a_S, the transistor NM0b_S may be turned off, and thus, the first sensing node SO0 may not be discharged.

Referring to FIGS. 11 and 12, in the SO sensing period 25, a set signal SET_S4 may have a high level. Therefore, a transistor NM4c_S may be turned on. When a level of the fifth sensing node SO4 is higher than a reference level ref, a transistor NM4d_S may be turned on. The transistor NM4c_S and the transistor NM4d_S may be turned on, and thus, the node N4b_S may be discharged. Therefore, data of a node N4a_S may be changed from ‘0’ to ‘1’. When a level of the fifth sensing node SO4 is lower than the reference level ref, the transistor NM4d_S may be turned off, and the data of the node N4a_S may be maintained to be ‘0’. The reference level ref may denote a threshold voltage level of the transistor NM4d_S. The reference level ref may be referred to as a sensing trip level.

That is, data of the node N0a_S may be transferred to the node N4a_S through a data dumping operation between the first sensing latch SL0 and the fifth sensing latch SL4. However, an implementation is not limited thereto, and data may be stored in one of the nodes N0a_S and N0b_S, and data may be transferred to one of the nodes N4a_S and N4b_S through a data dumping operation.

In some implementations, by performing an operation on the first sensing latch SL0 in the second core operation sequence including the MON precharging period 30, the parasitic capacitor Cp0_S may be precharged, and thus, the node MON_S0 may be precharged. Accordingly, the occurrence of charge sharing between a capacitor connected to a corresponding sensing node and a parasitic capacitor corresponding to a parasitic capacitance may be prevented in the discharging period 23 of the data dumping period 20.

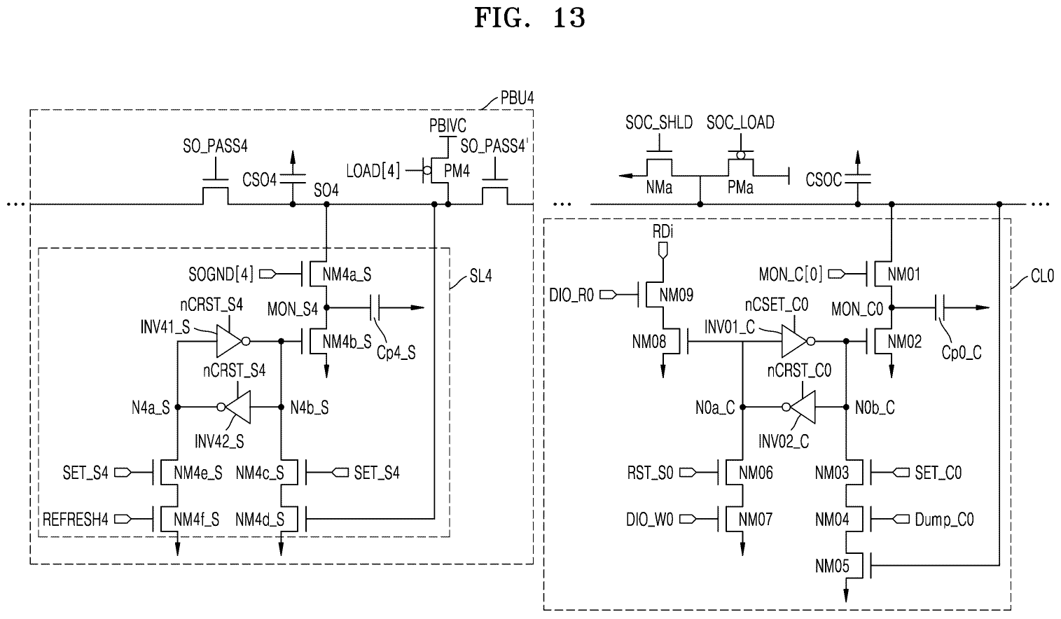

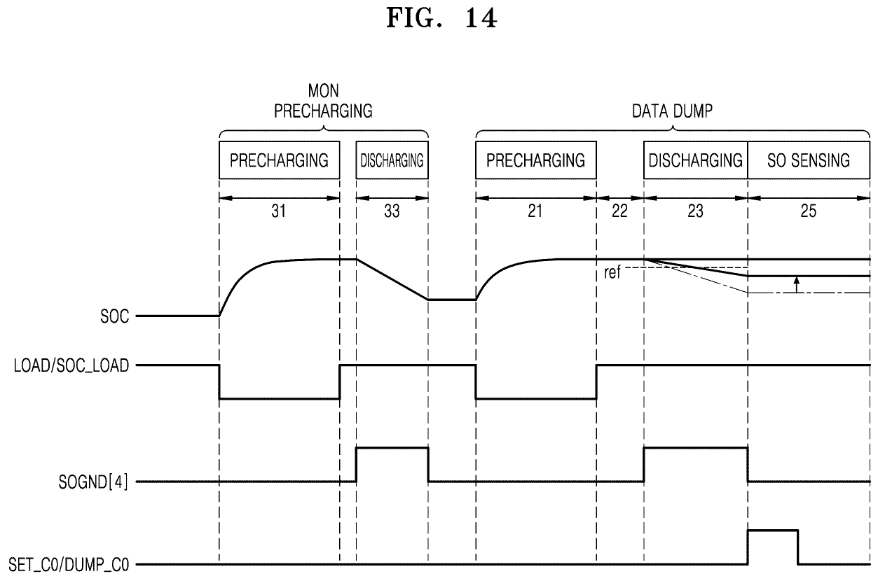

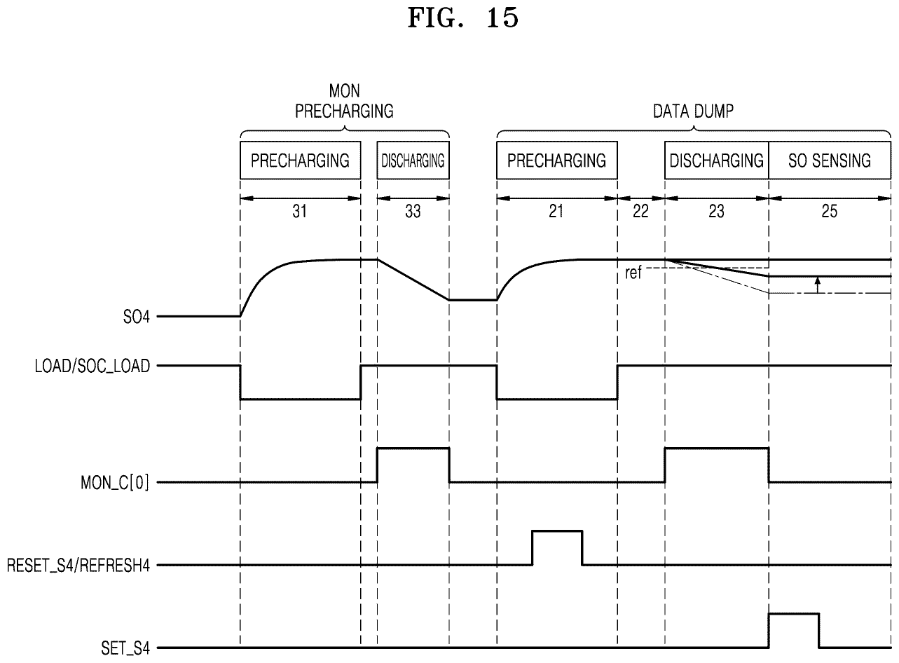

FIG. 13 is a circuit diagram describing an example of a data dumping operation between a main latch and a cache latch. FIG. 14 is a timing diagram of an example of a data dumping operation of transferring data from a main latch to a cache latch. FIG. 15 is a timing diagram of an example of a data dumping operation of transferring data from a cache latch to a main latch.

In detail, a data dumping operation between a first cache latch CL0 and a fifth cache latch CL4 included in a fifth page buffer unit PBU0 may be described with reference to FIGS. 13 and 14.

Referring to FIG. 13, a fifth page buffer unit PBU4 may have the same structure as that of the first page buffer unit PBU0 of FIG. 9. For example, the fifth page buffer unit PBU4 may further include a fifth force latch, a fifth upper bit latch, or a fifth lower bit latch.

In a state where sixth to eighth sensing nodes SO5 to SO7 are electrically connected to a combined sensing node SOC, a data dumping operation of transferring data of a fifth sensing latch SL4 to a first sensing latch SL0 may be performed.

However, the present disclosure is not limited thereto, and the fifth sensing latch SL4 may correspond to an arbitrary main latch connected to a sensing node SO. Also, the first cache latch CL0 may correspond to an arbitrary cache latch connected to the combined sensing node SOC.

For example, the fifth sensing latch SL4 may be a main latch (for example, a sensing latch, an upper bit latch, or a lower bit latch) included in an arbitrary page buffer unit PBU.

Hereinafter, a data dumping operation between the first cache latch CL0 and the fifth sensing latch SL4 will be described. First, a data dumping operation of transferring data from the fifth sensing latch SL4 to the first cache latch CL0 may be described with reference to FIGS. 13 and 14, and a data dumping operation of transferring data from the first cache latch CL0 to the fifth sensing latch SL4 may be described with reference to FIGS. 13 and 15.

Here, sixth to eighth sensing nodes SO5 to SO7 may be electrically connected to a combined sensing node SOC. Referring to FIG. 7, a pass control signal SO_PASS[7:6] and a pass control signal SO_PASS′[7:5] may be activated. That is, the pass control signal SO_PASS[7:6] and the pass control signal SO_PASS′[7:5] may have a high level. In some implementations, a pass control signal SO_PASS[5] may also have a high level.

Referring to FIGS. 14 and 15, a data dumping period 20 may include a precharging period 21 where a sensing node SO and a combined sensing node SOC are precharged, a time period 22, a discharging period 23 where the sensing node SO and the combined sensing node SOC are discharged, and an SO sensing period 25 where the sensing node SO is sensed. Here, the time period 22 and the discharging period 23 may be referred to as an SO develop period, and the discharging period 23 may be referred to as an SO develop period.

Also, referring to FIG. 14, the second core operation sequence may include an MON precharging period 30 before the precharging period 21. An MON precharging period 30 may include a precharging period 31 where the sensing node SO and the combined sensing node SOC are precharged and a discharging period 33 where the sensing node SO and the combined sensing node SOC are discharged.

Also, referring to FIGS. 13 and 14, an example may be described where data sensed in the data sensing period 10 of FIG. 10 is stored in a node NOa_S of a fifth sensing latch SL4 before the MON precharging period 30. Furthermore, a node Nob_C of a first cache latch CL5 may be previously set to store ‘1’, and a node Noa_C may be previously set to store ‘0’.

Referring to FIGS. 13 and 14, in the precharging period 31, a load signal LOAD[4] and a combined sensing node load signal SOC_LOAD may have a low level, a transistor PM4 may precharge the fifth sensing node SO4, and a transistor PMa may precharge the combined sensing node SOC. Although not shown in FIG. 13, in the precharging period 31, the sixth to eighth sensing nodes SO5 to SO7 disposed between the fifth sensing node SO4 and the combined sensing node SOC may also be precharged by transistors PM5 to PM7, based on a load signal LOAD[7:5] having a low level.

Referring to FIGS. 13 and 14, in the discharging period 33, the load signal LOAD[4] and the combined sensing node load signal SOC_LOAD may have a high level, and a ground control signal SOGND[4] may have a high level. Therefore, a transistor NM4a_S may be turned on. As the transistor NM4a_S is turned on, a parasitic capacitor Cp4_S may be precharged. That is, as the parasitic capacitor Cp4_S is precharged, a node MON_S4 may be precharged.

Referring to FIGS. 13 and 14, in the precharging period 21, the load signal LOAD[4] and the combined sensing node load signal SOC_LOAD may have a low level, the transistor PM4 may precharge the fifth sensing node SO4, and the transistor PMa may precharge the combined sensing node SOC. Although not shown in FIG. 13, in the precharging period 21, the sixth to eighth sensing nodes SO5 to SO7 disposed between the fifth sensing node SO4 and the combined sensing node SOC may also be precharged by the transistors PM5 to PM7, based on the load signal LOAD[7:5] having a low level.

Referring to FIGS. 13 and 14, in the precharging period 23, the ground control signal SOGND[4] may have a high level. Therefore, the transistor NM4a_S may be turned on. When ‘0’ is stored in a node N4a_S, a transistor NM4b_S may be turned on, and thus, the fifth sensing node SO4 may be discharged. As described above, because the sixth to eighth sensing nodes SO5 to SO7 are electrically connected to the combined sensing node SOC, the fifth sensing node SO4 may be discharged, and thus, the combined sensing node SOC may be discharged. When ‘1’ is stored in the node N4a_S, the transistor NM4b_S may be turned off, and thus, the fifth sensing node SO4 may not be discharged.

Referring to FIGS. 13 and 14, in an SO sensing period 25, a set signal SET_C0 and a dummy control signal DUMP_C0 may have a high level. Therefore, a transistor NM03 and a transistor NM04 may be turned on. When a level of the combined sensing node SOC is higher than a reference level ref, a transistor NM05 may be turned on. The transistor NM03, the transistor NM04, and the transistor NM05 may be turned on, and thus, the node N0b_C may be discharged. Therefore, data of a node N0a_C may be changed from ‘0’ to ‘1’. When a level of the combined sensing node SOC is lower than the reference level ref, the transistor NM05 may be turned off, and the data of the node N0a_C may be maintained to be ‘0’. The reference level ref may denote a threshold voltage level of the transistor NM05. The reference level ref may be referred to as a sensing trip level.

That is, data of the node N4a_S may be transferred to the node N0a_C through a data dumping operation between the first cache latch CL0 and the fifth sensing latch SL4. However, an implementation is not limited thereto, and data may be stored in one of the nodes N4a_S and N4b_S, and data may be transferred to one of the nodes N0a_C and N0b_C through a data dumping operation.

Hereinafter, a data dumping operation of transferring data from the first cache latch CL0 to the fifth sensing latch SL4 will be described with reference to FIGS. 13 and 15.

Referring to FIGS. 14 and 15, a data dumping period 20 may include a precharging period 21 where a sensing node SO and a combined sensing node SOC are precharged, a time period 22, a discharging period 23 where the sensing node SO and the combined sensing node SOC are discharged, and an SO sensing period 25 where the sensing node SO is sensed. Here, the time period 22 and the discharging period 23 may be referred to as an SO develop period, and the discharging period 23 may be referred to as an SO develop period.

Also, referring to FIG. 15, the second core operation sequence may include an MON precharging period 30 before the precharging period 21. An MON precharging period 30 may include a precharging period 31 where the sensing node SO and the combined sensing node SOC are precharged and a discharging period 33 where the sensing node SO and the combined sensing node SOC are discharged.

Also, referring to FIGS. 13 and 15, an example where data is stored in a node N0a_C of the first cache latch CL0 before the MON precharging period 30 will be described. For example, it may be previously set that, as a write control signal DIO_WO and a reset signal RST_S0 are activated, the node N0a_C is discharged, and thus, a node N0b_C of the first cache latch CL5 stores ‘1’, and the node N0a_C stores ‘0’.

Referring to FIGS. 13 and 15, in the precharging period 31, a load signal LOAD[4] and a combined sensing node load signal SOC_LOAD may have a low level, a transistor PM4 may precharge the fifth sensing node SO4, and a transistor PMa may precharge the combined sensing node SOC. Although not shown in FIG. 13, in the precharging period 31, the sixth to eighth sensing nodes SO5 to SO7 disposed between the fifth sensing node SO4 and the combined sensing node SOC may also be precharged by transistors PM5 to PM7, based on a load signal LOAD[7:5] having a low level.

Referring to FIGS. 13 and 15, in the discharging period 33, the load signal LOAD[4] and the combined sensing node load signal SOC_LOAD may have a high level, and a cache monitoring signal MON_C[0] may have a high level. Therefore, the transistor NM01 may be turned on. As the transistor NM01 is turned on, a parasitic capacitor Cp0_C may be precharged. That is, as the parasitic capacitor Cp0_C is precharged, a node MON_C0 may be precharged.

Referring to FIGS. 13 and 15, in the precharging period 21, a load signal LOAD[4] and a combined sensing node load signal SOC_LOAD may have a low level, a transistor PM4 may precharge the fifth sensing node SO4, and a transistor PMa may precharge the combined sensing node SOC. Although not shown in FIG. 13, in the precharging period 31, the sixth to eighth sensing nodes SO5 to SO7 disposed between the fifth sensing node SO4 and the combined sensing node SOC may also be precharged by transistors PM5 to PM7, based on a load signal LOAD[7:5] having a low level.

Also, in the precharging period 21, a reset signal RST_S4 and a refresh signal REFRESH4 may have a high level. Accordingly, a transistor NM4e_S and a transistor NM4f_S may be turned on, and thus, a node N4a_S may be discharged. That is, ‘0’ may be stored in the node N4a_S, and ‘1’ may be stored in a node N4b_S.

Referring to FIGS. 13 and 15, in the precharging period 23, the cache monitoring signal MON_C[0] may have a high level. Therefore, the transistor NM01 may be turned on. As described above, because ‘0’ is stored in the node N0a_C, a transistor NM02 may be turned on, and thus, the combined sensing node SOC may be discharged. Also, as described above, because the sixth to eighth sensing nodes SO5 to SO7 are electrically connected to the combined sensing node SOC, the combined sensing node SOC may be discharged, and thus, the fifth sensing node SO4 may be discharged.

Referring to FIGS. 13 and 15, in the SO sensing period 25, a set signal SET_C4 may have a high level. Therefore, a transistor NM4c_S may be turned on. When a level of the fifth sensing node SO4 is higher than a reference level ref, a transistor NM4d_S may be turned on, and as the transistor NM4c_S and the transistor NM4d_S are turned on, a node N4b_S may be discharged. Therefore, data of a node N4a_S may be changed from ‘0’ to ‘1’. When a level of the fifth sensing node SO4 is lower than the reference level ref, the transistor NM4d_S may be turned off, and the data of the node N4a_S may be maintained to be ‘0’. The reference level ref may denote a threshold voltage level of the transistor NM4d_S. The reference level ref may be referred to as a sensing trip level.

That is, data of the node N0a_C may be transferred to the node N4a_S through a data dumping operation between the first cache latch CL0 and the fifth sensing latch SL4. However, an implementation is not limited thereto, and data may be stored in one of the nodes N0a_S and N0b_S, and data may be transferred to one of the nodes N4a_C and N4b_C through a data dumping operation.

In some implementations, by performing an operation on the first cache latch CL0 in the second core operation sequence including the MON precharging period 30, the parasitic capacitor Cp0_C may be precharged, and thus, the node MON_C0 may be precharged. Accordingly, the occurrence of charge sharing between a capacitor connected to a combined sensing node and a parasitic capacitor corresponding to a parasitic capacitance may be prevented in the discharging period 23 of the data dumping period 20.

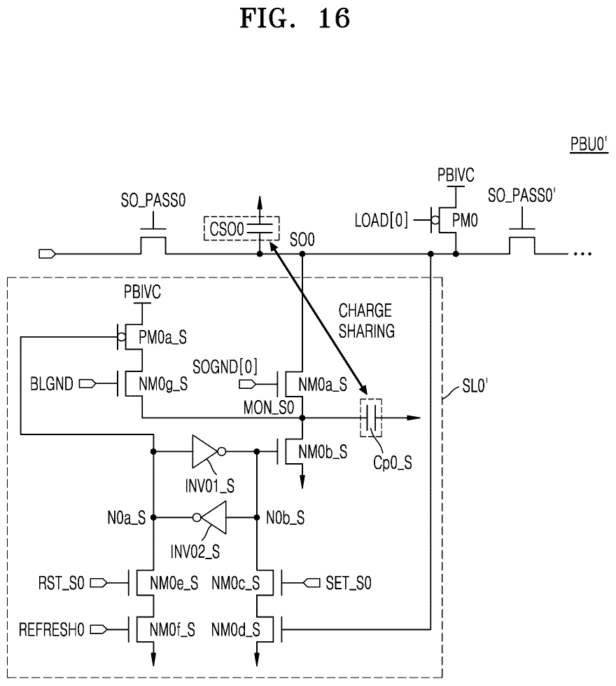

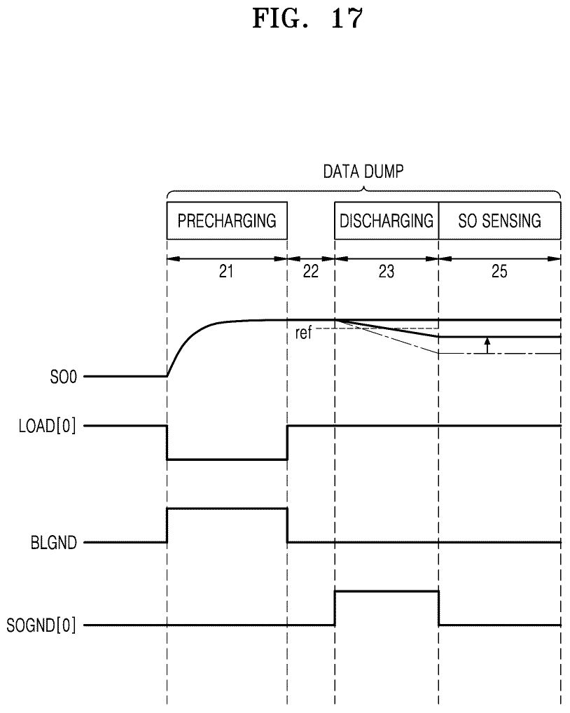

FIG. 16 is a circuit diagram illustrating in detail an example of a sensing latch SL0′. FIG. 17 is a timing diagram of an example of a data dumping operation of transferring data from the sensing latch SL0′ to a target latch. A first sensing latch SL0′ of FIG. 16 may correspond to an implementation example of the sensing latch SL described above with reference to FIG. 5, and the first sensing latch SL0′ of FIG. 16 may correspond to a modification example of the first sensing latch SL0 of FIG. 8.

Comparing with the first sensing latch SL0 of FIG. 8, the first sensing latch SL0′ of FIG. 16 may further include a transistor NM0g_S and a transistor PM0a_S. Here, the transistor NM0g_S may be implemented as an N-channel transistor, and the transistor PM0a_S may be implemented as a P-channel transistor.

A gate terminal of the transistor NM0g_S may be connected to a bit line reference voltage signal BLGND line. That is, the transistor NM0g_S may be driven by a bit line reference voltage signal BLGND.

Also, the transistor NM0g_S may be connected between the transistor PM0a_S and a node MON_S0. For example, a drain terminal of the transistor NM0g_S may be connected to the node MON_S0, and a source terminal of the transistor NM0g_S may be connected to a drain terminal of the transistor PM0a_S.

Referring to FIG. 16, a gate terminal of the transistor PM0a_S may be connected to a node N0a_S0. That is, the transistor PM0a_S may be driven by a voltage level of the node N0a_S0.

In some implementations, unlike the illustration of FIG. 16, a gate terminal of the transistor PM0a_S may be connected to the node N0b_S0. That is, the transistor PM0b_S may be driven by a voltage level of the node N0a_S0.

Also, the transistor PM0a_S may be connected between the transistor NM0g_S and a voltage terminal to which a precharge voltage PBIVC (for example, VDD) is applied. For example, a source terminal of the transistor PM0a_S may be connected to a precharge voltage PBIVC line, and a drain terminal of the transistor PM0a_S may be connected to the source terminal of the transistor NM0g_S.

The first sensing latch SL0′ of FIG. 16 may operate based on the first core operation sequence. Also, in the precharging period 21 of the first core operation sequence, the node MON_S0 may be precharged to prevent the occurrence of charge sharing between a capacitor CSO0 and a parasitic capacitor Cp0_S, and thus, may prevent the drop of voltage level of the node SO0 caused by a parasitic capacitance (for example, the parasitic capacitor Cp0_S). This will be additionally described with reference to FIG. 17.

Referring to FIGS. 16 and 17, a data dumping operation of transferring data of the first sensing latch SL0′ to a target latch may be performed.

Here, the target latch may be an arbitrary main latch which shares a first sensing node SO0 or an arbitrary cache latch which shares the combined sensing node SOC capable of being connected to the first sensing node SO0. However, the present disclosure is not limited thereto, and the first sensing latch SL0 may correspond to an arbitrary main latch (for example, a first force latch, a first upper bit latch, or a first lower bit latch, or a second sensing latch) connected to the sensing node SO.

Also, a node (a corresponding sensing node or a corresponding combined sensing node) corresponding to the target latch may be electrically connected to the first sensing node SO0.

For example, when the target latch is a fifth sensing latch SL4, first to fifth sensing nodes SO0 to SO4 may be electrically connected to one another. Referring to FIG. 7, a pass control signal SO_PASS[4:1] and a pass control signal SO_PASS′[4:1] may be activated. That is, the pass control signal SO_PASS[4:1] and the pass control signal SO_PASS′[4:1] may have a high level. In some implementations, a pass control signal SO_PASS' [4] may also have a high level.

Also, for example, when the target latch is a first cache latch CL0, sixth to eighth sensing nodes SO5 to SO7 may be electrically connected to the combined sensing node SOC. Referring to FIG. 7, a pass control signal SO_PASS[7:6] and a pass control signal SO_PASS′[7:5] may be activated. That is, the pass control signal SO_PASS[7:6] and the pass control signal SO_PASS′[7:5] may have a high level. In some implementations, a pass control signal SO_PASS[5] may also have a high level.

Referring to FIG. 17, a data dumping period 20 may include a precharging period 21 where the sensing node SO is precharged, a time period 22, a discharging period 23 where the sensing node SO is discharged, and an SO sensing period 25 where the sensing node SO is sensed. Here, the time period 22 and the discharging period 23 may be referred to as an SO develop period, and the discharging period 23 may be referred to as an SO develop period.

Comparing with FIGS. 12, 14, and 15, a first core operation sequence of FIG. 17 may not include the precharging period 31 and the discharging period 33 of the second core operation sequence. That is, a first core operation sequence of FIG. 16 may include each of the precharging period 21 and the discharging period 23 once.

Referring to FIGS. 16 and 17, in the precharging period 21, a load signal LOAD[0] may have a low level, and a transistor PM0 may precharge the first sensing node SO0. Although not shown in FIG. 16, in the precharging period 21, a combined sensing node or a sensing node between the first sensing node SO0 and a node corresponding to the target latch may also be precharged by a combined sensing node load signal or a load signal having a low level.

Also, in the precharging period 21, a bit line reference voltage signal BLGND may have a high level. Therefore, the transistor NM0g_S may be turned on. When ‘0’ is stored in the node N0a_S, the transistor PM0a_S may be turned on. As the transistor NM0g_S and the transistor PM0a_S are turned on, the precharge voltage PBIVC line may be connected to the parasitic capacitor Cp0_S. Therefore, the parasitic capacitor Cp0_S may be precharged by the precharge voltage PBIVC line. That is, as the parasitic capacitor Cp0_S is precharged, a node MON_S0 may be precharged. When ‘1’ is stored in the node NOa_S, the transistor PM0a_S may be turned off, and thus, the node MON_S0 may not be discharged.

Referring to FIGS. 16 and 17, in the precharging period 23, the ground control signal SOGND[0] may have a high level. Therefore, a transistor NM0a_S may be turned on. When ‘0’ is stored in the node N0a_S, a transistor NM0b_S may be turned on, and thus, the first sensing node SOO may be discharged. As described above, because a node (a corresponding sensing node or a corresponding combined sensing node) corresponding to the target latch is electrically connected to the first sensing node SO0, the first sensing node SO0 may be discharged, and thus, the node (the corresponding sensing node or the corresponding combined sensing node) corresponding to the target latch may also be discharged. When ‘1’ is stored in the node N0a_S, the transistor NM0b_S may be turned off, and thus, the first sensing node SO0 may not be discharged.

Although not shown, in the SO sensing period 25, a set signal corresponding to the target latch may have a high level. Accordingly, a voltage level of a sensing node or a combined sensing node corresponding to the target latch may be compared with the reference level ref, and thus, data may be stored in the target latch.

That is, data of the node N0a_S may be transferred to the target latch through a data dumping operation between the first sensing latch SL0′ and the target latch. However, an implementation is not limited thereto, and data may be stored in one of the nodes N0a_S and N0b_S.

In some implementations, the precharge voltage PBIVC line may be connected to the parasitic capacitor Cp0_S in the precharging period 21 of the data dumping period 20 of the first core operation sequence on the first sensing latch SL0′, and thus, the parasitic capacitor Cp0_S may be precharged by the precharge voltage PBIVC line. Accordingly, the occurrence of charge sharing between a capacitor connected to a corresponding sensing node and a parasitic capacitor corresponding to a parasitic capacitance may be prevented in the discharging period 23 of the data dumping period 20.

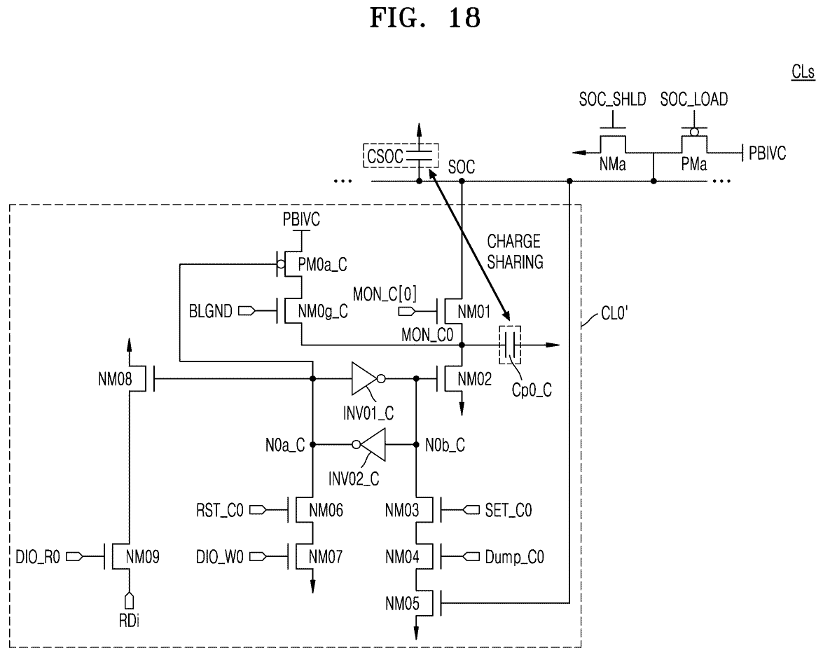

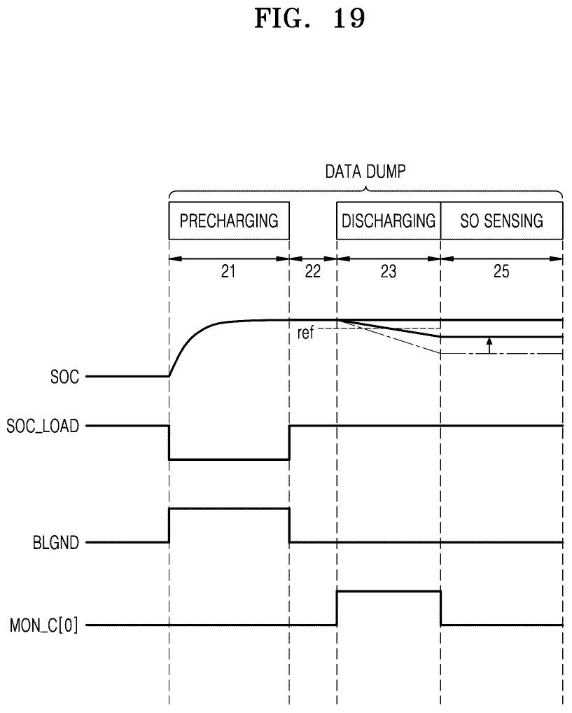

FIG. 18 is a circuit diagram illustrating in detail an example of a cache latch CL0′. FIG. 19 is a timing diagram of an example of a data dumping operation of transferring data from the cache latch CL0′ to a target latch.

A first cache latch CL0′ of FIG. 18 may correspond to an implementation example of the cache latch CL described above with reference to FIG. 5, and the first cache latch CL0′ of FIG. 18 may correspond to a modification example of the first cache latch CL0 of FIG. 9.

Comparing with the first cache latch CL0 of FIG. 9, the first cache latch CL0′ of FIG. 16 may further include a transistor NM0g_C and a transistor PM0a_C. Here, the transistor NM0g_C may be implemented as an N-channel transistor, and the transistor PM0a_C may be implemented as a P-channel transistor.

A gate terminal of the transistor NM0g_C may be connected to a bit line reference voltage signal BLGND line. That is, the transistor NM0g_C may be driven by a bit line reference voltage signal BLGND.

Also, the transistor NM0g_C may be connected between the transistor PM0a_C and a node MON_C0. For example, a drain terminal of the transistor NM0g_C may be connected to the node MON_C0, and a source terminal of the transistor NM0g_C may be connected to a drain terminal of the transistor PM0a_C.

Referring to FIG. 18, a gate terminal of the transistor PM0a_C may be connected to a node N0a_C0. That is, the transistor PM0a_C may be driven by a voltage level of the node N0a_C0.

In some implementations, unlike the illustration of FIG. 18, a gate terminal of the transistor PM0a_S may be connected to the node N0b_S0. That is, the transistor PM0b_S may be driven by a voltage level of the node N0a_S0.

Also, the transistor PM0a_C may be connected between the transistor NM0g_C and a voltage terminal to which a precharge voltage PBIVC (for example, VDD) is applied. For example, a source terminal of the transistor PM0a_C may be connected to a precharge voltage PBIVC line, and a drain terminal of the transistor PM0a_C may be connected to the source terminal of the transistor NM0g_C.

The first cache latch CL0′ of FIG. 18 may operate based on the first core operation sequence. Also, in the precharging period 21 of the first core operation sequence, the node MON_C0 may be precharged to prevent the occurrence of charge sharing between a capacitor CSOC and a parasitic capacitor Cp0_C, and thus, may prevent the drop of voltage level of the node SOC caused by a parasitic capacitance (for example, the parasitic capacitor Cp0_C). This will be additionally described with reference to FIG. 19.

Referring to FIGS. 18 and 19, a data dumping operation of transferring data of the first cache latch CL0′ to a target latch may be performed.

Here, the target latch may be a main latch connected to an arbitrary sensing node capable of being connected to a combined sensing node SOC. For example, the target latch may correspond to an arbitrary main latch (for example, a first sensing latch, a first force latch, a first upper bit latch, or a first lower bit latch, or a second sensing latch) connected to a sensing node SO.

Also, a node (a corresponding sensing node) corresponding to the target latch may be electrically connected to the combined sensing node SOC.

For example, when the target latch is a fifth sensing latch SL4, sixth to eighth sensing nodes SO5 to SO7 may be electrically connected to the combined sensing node SOC. Referring to FIG. 7, a pass control signal SO_PASS[7:6] and a pass control signal SO_PASS′[7:5] may be activated. That is, the pass control signal SO_PASS[7:6] and the pass control signal SO_PASS′[7:5] may have a high level. In some implementations, a pass control signal SO_PASS[5] may also have a high level.

Hereinafter, an example where the target latch is the fifth sensing latch SL4 will be described.

Referring to FIG. 19, a data dumping period 20 may include a precharging period 21 where the sensing node SO is precharged, a time period 22, a discharging period 23 where the sensing node SO is discharged, and an SO sensing period 25 where the sensing node SO is sensed. Here, the time period 22 and the discharging period 23 may be referred to as an SO develop period, and the discharging period 23 may be referred to as an SO develop period.

Comparing with FIGS. 12, 14, and 15, a first core operation sequence of FIG. 19 may not include the precharging period 31 and the discharging period 33 of the second core operation sequence. That is, a first core operation sequence of FIG. 16 may include each of the precharging period 21 and the discharging period 23 once.

Referring to FIGS. 18 and 19, in the precharging period 21, a combined sensing node load signal SOC_LOAD may have a low level, and a transistor PMa may precharge the combined sensing node SOC. Although not shown in FIG. 16, in the precharging period 21, the fifth sensing node SO4 and sensing nodes between the fifth sensing node SO4 and the combined sensing node SOC may be precharged by a load signal having a low level.

Also, in the precharging period 21, a bit line reference voltage signal BLGND may have a high level. Therefore, the transistor NM0g_C may be turned on. When ‘0’ is stored in the node N0a_C, the transistor PM0a_C may be turned on. As the transistor NM0g_C and the transistor PM0a_C are turned on, the precharge voltage PBIVC line may be connected to the parasitic capacitor Cp0_C. Therefore, the parasitic capacitor Cp0_C may be precharged by the precharge voltage PBIVC line. That is, as the parasitic capacitor Cp0_C is precharged, a node MON_C0 may be precharged. When ‘1’ is stored in the node N0a_C, the transistor PM0a_C may be turned off, and thus, the node MON_C0 may not be discharged.

Referring to FIGS. 18 and 19, in the precharging period 23, the cache monitoring signal MON_C[0] may have a high level. Therefore, the transistor NM01 may be turned on. When ‘0’ is stored in the node N0a_C, a transistor NM02 may be turned on, and thus, the combined sensing node SOC may be discharged. As described above, because a node (a corresponding sensing node) (for example, the fifth sensing node SO4) corresponding to the target latch is electrically connected to the combined sensing node SOC, the combined sensing node SOC may be discharged, and thus, the node (the corresponding sensing node) (for example, the fifth sensing node SO4) corresponding to the target latch may also be discharged. When ‘1’ is stored in the node N0a_C, the transistor NM02 may be turned off, and thus, the combined sensing node SOC may not be discharged.

Although not shown, in the SO sensing period 25, a set signal (for example, SET_S4) corresponding to the target latch may have a high level. Accordingly, a voltage level of a sensing node or a combined sensing node corresponding to the target latch may be compared with the reference level ref, and thus, data may be stored in the target latch (for example, the fifth sensing latch SL4).

That is, data of the node N0a_C may be transferred to the target latch through a data dumping operation between the first sensing latch SL0′ and the target latch. However, an implementation is not limited thereto, and data may be stored in one of the nodes N0a_C and N0b_C.

In some implementations, the precharge voltage PBIVC line may be connected to the parasitic capacitor Cp0_C in the precharging period 21 of the data dumping period 20 of the first core operation sequence on the first cache latch CL0′, and thus, the parasitic capacitor Cp0_C may be precharged by the precharge voltage PBIVC line. Accordingly, the occurrence of charge sharing between a capacitor connected to a combined sensing node and a parasitic capacitor corresponding to a parasitic capacitance may be prevented in the discharging period 23 of the data dumping period 20.

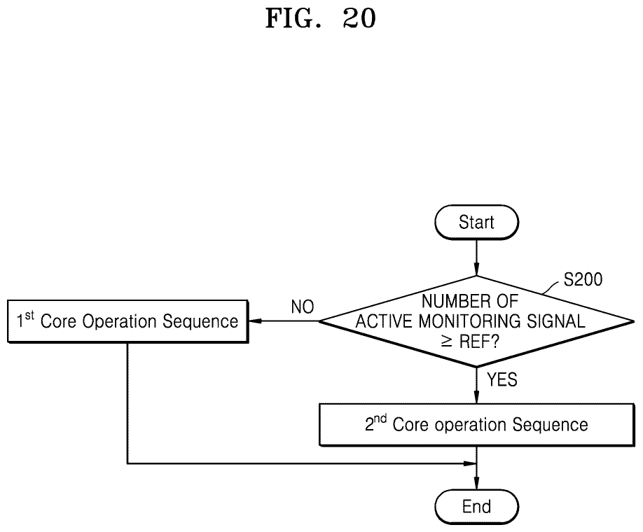

FIG. 20 is a flowchart illustrating an example of an operation of a page buffer circuit.

Each of page buffer units PBU included in the page buffer circuit 120 may perform a data dumping operation in parallel.

For example, referring to FIG. 3, data may be dumped from the third page buffer PBU3 into the first cache latch CL0 when dumping data from a main latch, included in the first page buffer unit PBU0, into a main latch included in the second page buffer unit PBU1.

At this time, in a case which performs a data dumping operation of dumping data from a latch, storing the data, into a target latch, a monitoring signal corresponding to the latch storing the data may be activated. For example, an activated monitoring signal may have a high level.

Also, referring to FIG. 5, the monitoring signal may include a ground control signal SOGND corresponding to a sensing latch SL, a force monitoring signal MON_F corresponding to a force latch FL, an upper bit monitoring signal MON_M corresponding to an upper bit latch ML, and a lower bit monitoring signal MON_L corresponding to a lower bit latch LL.

In some implementations, the page buffer circuit 120 may operate in a first core operation sequence or a second core operation sequence, based on the number of activated monitoring signals. Here, a description of the first core operation sequence or the second core operation sequence may be replaced with the descriptions of FIGS. 10 to 19.

Referring to FIG. 20, in operation S200, when the number of activated monitoring signals is more than or equal to a predetermined number, the page buffer circuit 120 may operate in the second core operation sequence.

Referring to FIG. 20, in operation S200, when the number of activated monitoring signals is more than or equal to the predetermined number, the page buffer circuit 120 may operate in the first core operation sequence.

Here, the second core operation sequence may further include an MON precharging period 30 compared to the first core operation sequence, and thus, the reference number REF of activated monitoring signals may be determined based on tradeoff between a time and a sensing margin. For example, when the number of activated monitoring signals is three or more, the page buffer circuit 120 may operate in the second core operation sequence.

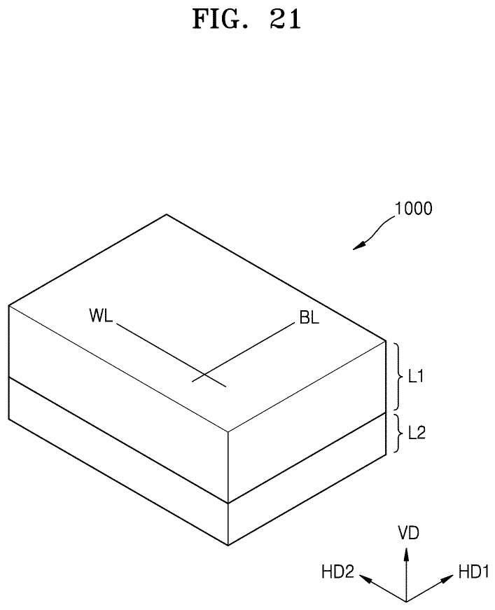

FIG. 21 illustrates an example of a memory device 1000 having a cell over peri (COP) structure.

Referring to FIG. 21 in conjunction with FIG. 1, the memory device 1000 may include a first semiconductor layer L1 and a second semiconductor layer L2, and the first semiconductor layer L1 may be stacked on the second semiconductor layer L2 in a vertical direction VD. In detail, the second semiconductor layer L2 may be disposed under the first semiconductor layer L1 in the vertical direction VD. The memory device 100 of FIG. 1 may have the COP structure like the memory device 1000.

In an implementation, the memory cell array 110 may be formed in the first semiconductor layer L1, and the control logic circuit 130, the row decoder 150, the voltage generator 140, and the page buffer circuit 120 may be formed in the second semiconductor layer L2. Therefore, the memory device 1000 may have a structure (i.e., the COP structure) where the memory cell array 110 is disposed on some peripheral circuits. The COP structure may effectively decrease a horizontal-direction area and may enhance the degree of integration of the memory device 1000.

In an implementation, the second semiconductor layer L2 may include a substrate, and as a pattern for wiring semiconductor devices and elements such as transistors is formed on the substrate, circuits may be formed in the second semiconductor layer L2. After the circuits are formed in the second semiconductor layer L2, the first semiconductor layer L1 including the memory cell array 110 may be formed, and patterns for electrically connecting word lines WL and bit lines BL of the memory cell array 110 to the circuits formed in the second semiconductor layer L2 may be formed.

In some implementations, the memory device 1000 may prevent charge sharing between a sensing node (or a combined sensing node) and a parasitic capacitor in a discharging period of a data dumping operation. That is, the memory device 1000 may be implemented by using the implementations described above with reference to FIGS. 1 to 20.

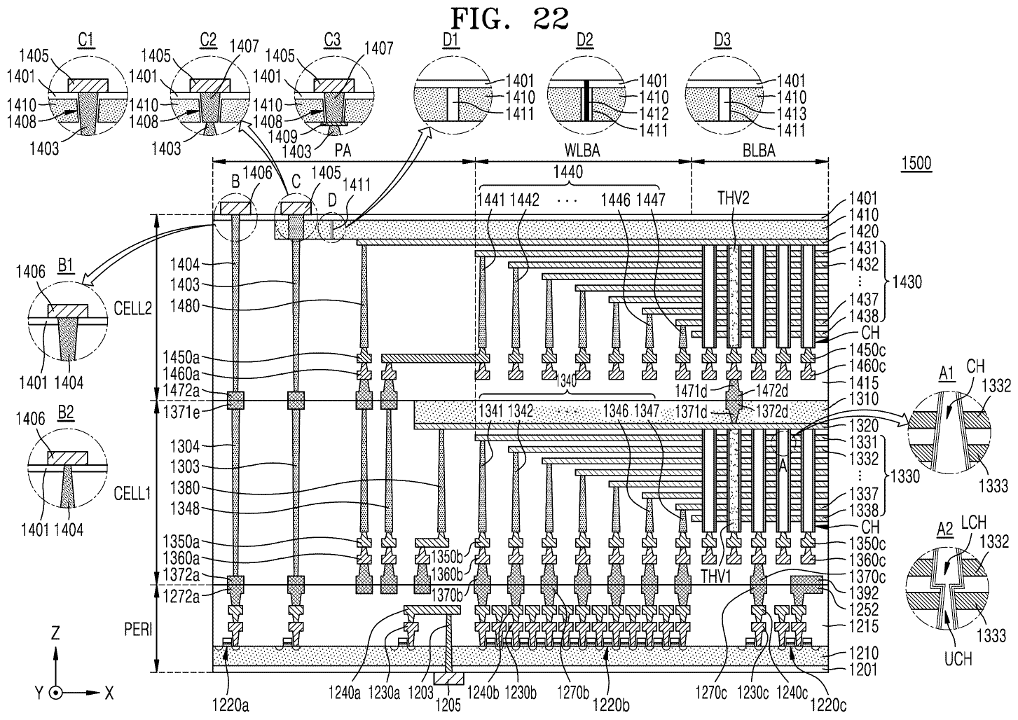

FIG. 22 is a cross-sectional view of an example of a memory device 1500 having a BVNAND structure. The memory device 100 of FIG. 1 may have a chip to chip (C2C) structure like the memory device 1500.

Referring to FIG. 22, the memory device 1500 may have the C2C structure. Here, the C2C structure may denote that each of at least one upper chip including a cell region CELL and a lower chip including a peripheral circuit region PERI is manufactured, and then, the at least one upper chip and the lower chip are connected to each other by a bonding process. For example, the bonding process may denote a process of electrically or physically connecting a bonding metal pattern, formed in an uppermost metal layer of an upper chip, to a bonding metal pattern formed in an uppermost metal layer of a lower chip. For example, when the bonding metal patterns include copper (Cu), the bonding process may be a Cu-Cu bonding process. As another example, the bonding metal patterns may include aluminum (Al) or tungsten (W).

The memory device 1500 may include one or more upper chips including a cell region. For example, as illustrated in FIG. 22, the memory device 1500 may be implemented to include two upper chips. However, this may be merely an implementation, and the number of upper chips is not limited thereto. In a case where the memory device 1500 is implemented to include two upper chips, each of a first upper chip including a first cell region CELL1, a second upper chip including a second cell region CELL2, and a lower chip including a peripheral circuit region PERI may be manufactured, and then, the first upper chip, the second upper chip, and the lower chip may be connected to one another by a bonding process, thereby manufacturing the memory device 1500. The first upper chip may be reversed and may be connected to the lower chip by a bonding process, and the second upper chip may be reversed and may be connected to the first upper chip by a bonding process. In the following description, upper portions and lower portions of the first and second upper chips may be defined with respect to before the first upper chip and the second upper chip are reversed. That is, in FIG. 22, an upper portion of the lower chip may denote an upper portion which is defined with respect to a +Z-axis direction, and an upper portion of each of the first and second upper chips may denote an upper portion which is defined with respect to a −Z-axis direction. However, this may be merely an implementation, and only one of the first upper chip and the second upper chip may be reversed and may be connected to each other by a bonding process.

Each of the peripheral circuit region PERI and the first and second cell regions CELL1 and CELL2 of the memory device 1500 may include an external pad bonding region PA, a word line bonding region WLBA, and a bit line bonding region BLBA.

The peripheral circuit region PERI may include a first substrate 1210 and a plurality of circuit elements 1220a to 1220c formed in the first substrate 1210. An interlayer insulation layer 1215 including one or more insulation layers may be provided on the plurality of circuit elements 1220a to 1220c, and a plurality of metal wirings connecting the plurality of circuit elements 1220a to 1220c with one another may be provided in the interlayer insulation layer 1215. For example, the plurality of metal wirings may include first metal wirings 1230a to 1230c respectively connected to the plurality of circuit elements 1220a to 1220c and second metal wirings 1240a to 1240c formed on the first metal wirings 1230a to 1230c. The plurality of metal wirings may include at least one of various conductive materials. For example, the first metal wirings 1230a to 1230c may include tungsten which is relatively high in electrical resistivity, and the second metal wirings 1240a to 1240c may include copper which is relatively low in electrical resistivity.

Herein, only the first metal wirings 1230a to 1230c and the second metal wirings 1240a to 1240c are illustrated and described, but the present disclosure is not limited thereto and one or more additional metal wirings may be further formed on the second metal wirings 1240a to 1240c. In this case, the second metal wirings 1240a to 1240c may include aluminum. Also, at least a portion of the additional metal wiring formed on the second metal wirings 1240a to 1240c may include copper having electrical resistivity which is lower than that of aluminum of the second metal wirings 1240a to 1240c.

The interlayer insulation layer 1215 may be disposed on the first substrate 1210 and may include an insulating material such as silicon oxide or silicon nitride.

Each of the first and second cell regions CELL1 and CELL2 may include at least one memory block. The first cell region CELL1 may include a second substrate 1310 and a common source line 1320. A plurality of word lines 1331 to 1338 (1330) may be stacked on the second substrate 1310 in a direction (a Z-axis direction) perpendicular to an upper surface of the second substrate 1310. String selection lines and a ground selection line may be disposed on and under the word lines 1330, and the plurality of word lines 1330 may be disposed between the string selection lines and the ground selection line. Likewise, the second cell region CELL2 may include a third substrate 1410 and a common source line 1420, and a plurality of word lines 1431 to 1438 (1430) may be stacked on the third substrate 1410 in a direction (the Z-axis direction) perpendicular to an upper surface of the third substrate 1410. The second substrate 1310 and the third substrate 1410 may include various materials, and for example, may be a substrate including a monocrystalline epitaxial layer grown on a monocrystalline silicon substrate, a silicon substrate, a silicon-germanium substrate, or a germanium substrate. A plurality of channel structures CH may be formed in each of the first and second cell regions CELL1 and CELL2.

In an implementation, as illustrated in A1, the channel structure CH may be provided in the bit line bonding region BLBA, and moreover, may extend in a direction perpendicular to an upper surface of the second substrate 1310 and may pass through the word lines 1330, the string selection lines, and the ground selection line. The channel structure CH may include a data storage layer, a channel layer, and a buried insulation layer. The channel layer may be electrically connected to a first metal wiring 1350c and a second metal wiring 1360c, in the bit line bonding region BLBA. For example, the second metal wiring 1360c may be a bit line and may be connected to the channel structure CH through the first metal wiring 1350c. The bit line may extend in a first direction (a Y-axis direction) parallel to the upper surface of the second substrate 1310.

In an implementation, as illustrated in A2, the channel structure CH may include a lower channel LCH and an upper channel UCH, which are connected to each other. For example, the channel structure CH may be formed through a process on the lower channel LCH and a process on the upper channel UCH. The lower channel LCH may extend in a direction perpendicular to the upper surface of the second substrate 1310 and may pass through the common source line 1320 and the lower word lines 1331 and 1332. The lower channel LCH may include a data storage layer, a channel layer, and a buried insulation layer and may be connected to the upper channel UCH. The upper channel UCH may pass through upper word lines 1333 to 1338. The upper channel UCH may include a data storage layer, a channel layer, and a buried insulation layer, and the channel layer of the upper channel UCH may be electrically connected to a first metal wiring 1350c and a second metal wiring 1360c. As a length of a channel increases, it may be difficult to form a channel having a certain width due to a process. The memory device 1500 may include a channel having improved width uniformity through the lower channel LCH and the upper channel UCH formed by a sequential process.

As illustrated in A2, in a case where the channel structure CH is formed to include the lower channel LCH and the upper channel UCH, a word line disposed near a boundary between the lower channel LCH and the upper channel UCH may be a dummy word line. For example, a word line 1332 and a word line 1333 each configuring a boundary between the lower channel LCH and the upper channel UCH may be a dummy word line. In this case, data may not be stored in memory cells connected to the dummy word line. Alternatively, the number of pages corresponding to the memory cells connected to the dummy word line may be less than the number of pages corresponding to memory cells connected to a general word line. A voltage level applied to the dummy word line may differ from a voltage level applied to the general word line, and thus, an adverse effect of a non-uniform channel width between the lower channel LCH and the upper channel UCH may decrease on an operation of a memory device.

Moreover, in A2, it is illustrated that the number of lower word lines 1331 and 1332 through which the lower channel LCH passes is less than the number of upper word lines 1333 to 1338 through which the upper channel UCH passes. However, this may be merely an implementation, and the present disclosure is not limited thereto. As another example, the number of lower word lines through which the lower channel LCH passes may be more than or equal to the number of upper word lines through which the upper channel UCH passes. Also, a structure and connection relationship of the channel structure CH disposed in the first cell region CELL1 described above may be identically applied to the channel structure CH disposed in the second cell region CELL2.

In the bit line bonding region BLBA, a first through via THV1 may be provided in the first cell region CELL1, and a second through via THV2 may be provided in the second cell region CELL2. As illustrated in FIG. 22, the first through via THV1 may pass through the common source line 1320 and a plurality of word lines 1330. However, this may be merely an implementation, and the first through via THV1 may further pass through the second substrate 1310. The first through via THV1 may include a conductive material. Alternatively, the first through via THV1 may include a conductive material which is surrounded by an insulating material. The second through via THV2 may be provided in the same shape and structure as those of the first through via THV1.

In an implementation, the first through via THV1 may be electrically connected to the second through via THV2 through a first through metal pattern 1372d and a second through metal pattern 1472d. The first through metal pattern 1372d may be formed at a lower end of the first upper chip including the first cell region CELL1, and the second through metal pattern 1472d may be formed at an upper end of the second upper chip including the second cell region CELL2. The first through via THV1 may be electrically connected to the first metal wiring 1350c and the second metal wiring 1360c. A lower via 1371d may be formed between the first through via THV1 and the first through metal pattern 1372d, and an upper via 1471d may be formed between the second through via THV2 and the second through metal pattern 1472d. The first through metal pattern 1372d may be connected to the second through metal pattern 1472d by a bonding process.

Also, in the bit line bonding region BLBA, an upper metal pattern 1252 may be formed in an uppermost metal layer of the peripheral circuit region PERI, and an upper metal pattern 1392 having the same shape as that of the upper metal pattern 1252 may be formed in an uppermost metal layer of the first cell region CELL1. The upper metal pattern 1392 of the first cell region CELL1 may be electrically connected to the upper metal pattern 1252 of the peripheral circuit region PERI by a bonding process. In the bit line bonding region BLBA, the bit line may be electrically connected to the page buffer included in the peripheral circuit region PERI. For example, some of the circuit elements 1220c of the peripheral circuit region PERI may provide a page buffer, and the bit line may be electrically connected to the circuit elements 1220c, providing the page buffer, through the upper bonding metal 1370c of the first cell region CELL1 and the upper bonding metal 1270c of the peripheral circuit region PERI.

Referring to FIG. 22, in the word line bonding region WLBA, the word lines 1330 of the first cell region CELL1 may extend in a second direction (an X-axis direction) parallel to an upper surface of the second substrate 1310 and may be connected to a plurality of cell contact plugs 1341 to 1347 (1340). A first metal wiring 1350b and a second metal wiring 1360b may be sequentially connected to upper portions of the cell contact plugs 1340 connected to the word lines 1330. The cell contact plugs 1340 may be connected to the peripheral circuit region PERI through an upper bonding metal 1370b of the first cell region CELL1 and an upper bonding metal 1270b of the peripheral circuit region PERI, in the word line bonding region WLBA.

The cell contact plugs 1340 may be electrically connected to a row decoder included in the peripheral circuit region PERI. For example, some of the circuit elements 1220b of the peripheral circuit region PERI may provide the row decoder, and the cell contact plugs 1340 may be electrically connected to the circuit elements 1220b, providing the row decoder, through the upper bonding metal 1370b of the first cell region CELL1 and the upper bonding metal 1270b of the peripheral circuit region PERI. In an implementation, an operation voltage of each of the circuit elements 1220b providing the row decoder may differ from an operation voltage of each of the circuit elements 1220c providing the page buffer. For example, the operation voltage of each of the circuit elements 1220c providing the page buffer may be greater than the operation voltage of each of the circuit elements 1220b providing the row decoder.

Likewise, in the word line bonding region WLBA, the word lines 1430 of the second cell region CELL2 may extend in the second direction (the X-axis direction) parallel to an upper surface of the third substrate 1410 and may be connected to a plurality of cell contact plugs 1441 to 1447 (1440). The cell contact plugs 1440 may be connected to the peripheral circuit region PERI through the upper metal pattern of the second cell region CELL2, the lower metal pattern of the first cell region CELL1, and the cell contact plug 1348.

In the word line bonding region WLBA, the upper bonding metal 1370b may be formed in the first cell region CELL1, and the upper bonding metal 1270b may be formed in the peripheral circuit region PERI. The upper bonding metal 1370b of the first cell region CELL1 may be electrically connected to the upper bonding metal 1270b of the peripheral circuit region PERI by a bonding process. The upper bonding metal 1370b and the upper bonding metal 1270b may include aluminum, copper, or tungsten.

In the external pad bonding region PA, a lower metal pattern 1371e may be in a lower portion of the first cell region CELL1, and an upper metal pattern 1472a may be in an upper portion of the second cell region CELL2. The lower metal pattern 1371e of the first cell region CELL1 may be connected to the upper metal pattern 1472a of the second cell region CELL2 by a bonding process, in the external pad bonding region PA. Likewise, an upper metal pattern 1372a may be formed in an upper portion of the first cell region CELL1, and an upper metal pattern 1272a may be formed in an upper portion of the peripheral circuit region PERI. The upper metal pattern 1372a of the first cell region CELL1 may be connected to the upper metal pattern 1272a of the peripheral circuit region PERI by a bonding process.

Common source line contact plugs 1380 and 1480 may be disposed in the external pad bonding region PA. The common source line contact plugs 1380 and 1480 may include a conductive material such as metal, a metal compound, or doped polysilicon. The common source line contact plug 1380 of the first cell region CELL1 may be electrically connected to the common source line 1320, and the common source line contact plug 1480 of the second cell region CELL2 may be electrically connected to the common source line 1420. A first metal wiring 1350a and a second metal wiring 1360a may be sequentially stacked on the common source line contact plug 1380 of the first cell region CELL1, and a first metal wiring 1450a and a second metal wiring 1460a may be sequentially stacked on the common source line contact plug 1480 of the second cell region CELL2.

I/O pads 1205, 1405, and 1406 may be disposed in the external pad bonding region PA. Referring to FIG. 22, a lower insulation layer 1201 may cover a lower surface of the first substrate 1210, and a first I/O pad 1205 may be formed on the lower insulation layer 1201. The first I/O pad 1205 may be connected to at least one of the plurality of circuit elements 1220a, disposed in the peripheral circuit region PERI, through a first I/O contact plug 1203 and may be isolated from the first substrate 1210 by the lower insulation layer 1201. Also, a side insulation layer may be disposed between the first I/O contact plug 1203 and the first substrate 1210 and may electrically disconnect the first I/O contact plug 1203 from the first substrate 1210.

An upper insulation layer 1401 covering the upper surface of the third substrate 1410 may be formed on the third substrate 1410. A second I/O pad 1405 and/or a third I/O pad 1406 may be disposed on the upper insulation layer 1401. The second I/O pad 1405 may be connected to at least one of the plurality of circuit elements 1220a, disposed in the peripheral circuit region PERI, through second I/O contact plugs 1403 and 1303, and the third I/O pad 1406 may be connected to at least one of the plurality of circuit elements 1220a, disposed in the peripheral circuit region PERI, through third I/O contact plugs 1404 and 1304.

In an implementation, the third substrate 1410 may not be disposed in a region where an I/O contact plug is disposed. For example, as illustrated in B, the third I/O contact plug 1404 may be isolated from the third substrate 1410 in a direction parallel to the upper surface of the third substrate 1410, and moreover, may pass through an interlayer insulation layer 1415 of the second cell region CELL2 and may be connected to the third I/O pad 1406. In this case, the third I/O contact plug 1404 may be formed by various processes.

For example, as illustrated in B1, the third I/O contact plug 1404 may extend in a third direction (a Z-axis direction) and may be formed so that a diameter thereof increases progressively toward the upper insulation layer 1401. That is, a diameter of the channel structure CH described with reference to A1 may be formed to decrease progressively toward the upper insulation layer 1401, and a diameter of the third I/O contact plug 1404 may increase progressively toward the upper insulation layer 1401. For example, the third I/O contact plug 1404 may be formed after the second cell region CELL2 is coupled to the first cell region CELL1 by a bonding process.

Also, as illustrated in B2, the third I/O contact plug 1404 may extend in a third direction (a Z-axis direction) and may be formed so that a diameter thereof decreases progressively toward the upper insulation layer 1401. That is, like the channel structure CH, a diameter of the third I/O contact plug 1404 may decrease progressively toward the upper insulation layer 1401. For example, the third I/O contact plug 1404 may be formed along with the cell contact plugs 1440 before the second cell region CELL2 is bonded to the first cell region CELL1.

In other implementations, an I/O contact plug may be disposed to overlap the third substrate 1410. For example, as illustrated in C, the second I/O contact plug 1403 may be formed to pass through the interlayer insulation layer 1415 of the second cell region CELL2 in the third direction (the Z-axis direction) and may be electrically connected to the second I/O pad 1405 through the third substrate 1410. In this case, a connection structure between the second I/O contact plug 1403 and the second I/O pad 1405 may be implemented as various types.

For example, as illustrated in C1, an opening portion 1408 passing through the third substrate 1410 may be formed, and the second I/O contact plug 1403 may be directly connected to the second I/O pad 1405 through the opening portion 1408 formed in the third substrate 1410. In this case, as illustrated in C1, a diameter of the second I/O contact plug 1403 may be formed to increase progressively toward the second I/O pad 1405. However, this may be merely an implementation, and a diameter of the second I/O contact plug 1403 may be formed to decrease progressively toward the second I/O pad 1405.

For example, as illustrated in C2, the opening portion 1408 passing through the third substrate 1410 may be formed, and a contact 1407 may be formed in the opening portion 1408. On end portion of the contact 1407 may be connected to the second I/O pad 1405, and the other end portion may be connected to the second I/O contact plug 1403. Therefore, the second I/O contact plug 1403 may be electrically connected to the second I/O pad 1405 through the contact 1407 of the opening portion 1408. In this case, as illustrated in C2, a diameter of the contact 1407 may increase progressively toward the second I/O pad 1405, and a diameter of the second I/O contact plug 1403 may be formed to decrease progressively toward the second I/O pad 1405. For example, the second I/O contact plug 1403 may be formed along with the cell contact plugs 1440 before the second cell region CELL2 is bonded to the first cell region CELL1, and the contact 1407 may be formed after the second cell region CELL2 is bonded to the first cell region CELL1.

Also, as illustrated in C3, a stopper 1409 may be further formed in an upper surface of the opening portion 1408 of the third substrate 1410 compared to C2. The stopper 1409 may be a metal wiring which is formed in the same layer as the common source line 1420. However, this may be merely an implementation, and the stopper 1409 may be a metal wiring which is formed in the same layer as at least one of the word lines 1430. The second I/O contact plug 1403 may be electrically connected to the second I/O pad 1405 through the contact 1407 and the stopper 1409.

Furthermore, similar to the second and third I/O contact plugs 1403 and 1404 of the second cell region CELL2, the second and third I/O contact plugs 1403 and 1404 of the first cell region CELL1 may be formed so that a diameter thereof decreases progressively toward the lower metal pattern 1371e, or increases progressively toward the lower metal pattern 1371c.

Moreover, according to implementations, a slit 1411 may be formed in the third substrate 1410. For example, the slit 1411 may be formed at an arbitrary position of the external pad bonding region PA. For example, as illustrated in D, as seen in a plane, the slit 1411 may be disposed between the second I/O pad 1405 and the cell contact plugs 1440. However, this may be merely an implementation, and the slit 1411 may be formed so that the second I/O pad 1405 is disposed between the slit 1411 and the cell contact plugs 1440.

For example, as illustrated in D1, the slit 1411 may be formed to pass through the third substrate 1410. The slit 1411, for example, may be formed to prevent the third substrate 1410 from being finely cracked when forming the opening portion 1408. However, this may be merely an implementation, and the slit 1411 may be formed to a depth equal to about 60% to about 70% of a thickness of the third substrate 1410.

Also, as illustrated in D2, a conductive material 1412 may be formed in the slit 1411. The conductive material 1412, for example, may be used for discharging a leakage current, occurring when circuit elements of the external pad bonding region PA are being driven, to the outside. In this case, the conductive material 1412 may be connected to an external ground line.

Also, as illustrated in D3, an insulating material 1413 may be formed in the slit 1411. The insulating material 1413, for example, may be formed for electrically disconnecting the word line bonding region WLBA from the second I/O pad 1405 and the second I/O contact plug 1403 each disposed in the external pad bonding region PA. The insulating material 1413 may be formed in the slit 1411 and may thus prevent a voltage, provided through the second I/O pad 1405, from affecting a metal layer disposed on the third substrate 1410 of the word line bonding region WLBA.

Moreover, according to implementations, the first to third I/O pads 1205, 1405, and 1406 may be selectively formed. For example, the memory device 1500 may be implemented to include only the first I/O pad 1205 disposed on the first substrate 1210, or include only the second I/O pad 1405 disposed on the third substrate 1410, or include only the third I/O pad 1406 disposed on the upper insulation layer 1401.

Furthermore, in some implementations, at least one of the second substrate 1310 of the first cell region CELL1 and the third substrate 1410 of the second cell region CELL2 may be used as a sacrificial substrate, and all or only a portion thereof may be removed before or after a bonding process. After a substrate is removed, an additional layer may be stacked. For example, the second substrate 1310 of the first cell region CELL1 may be removed before or after bonding of the peripheral circuit region PERI and the first cell region CELL1, and an insulation layer covering an upper surface of the common source line 1320 or a conductive layer for connection may be formed. Similarly, the third substrate 1410 of the second cell region CELL2 may be removed before or after bonding of the first cell region CELL1 and the second cell region CELL2, and an upper insulation layer 1401 covering an upper surface of the common source line 1420 or a conductive layer for connection may be formed.

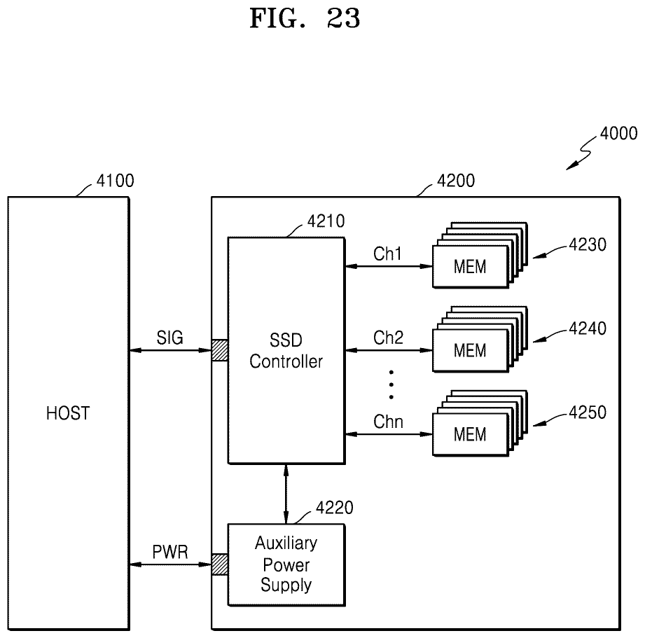

FIG. 23 is a block diagram illustrating an example where a memory device is applied to a solid state drive (SSD) system 4000.

Referring to FIG. 23, the SSD system 4000 may include a host 4100 and an SSD 4200.

The SSD 4200 may transmit or receive a signal to or from the host 4100 through a signal connector and may be supplied with power through a power connector. The SSD 4200 may include an SSD controller 4210, an auxiliary power supply 4220, and memory devices 4230, 4240, and 4250. Each of the memory devices 4230, 4240, and 4250 may be a vertical stack-type NAND flash memory device. In this case, the memory devices 4230, 4240, and 4250 may be implemented by using the implementations described above with reference to FIGS. 1 to 22.

Hereinabove, exemplary implementations have been described in the drawings and the specification. Implementations have been described by using the terms described herein, but this has been merely used for describing the present disclosure and has not been used for limiting a meaning or limiting the scope of the present disclosure defined in the following claims. Therefore, it may be understood by those of ordinary skill in the art that various modifications and other equivalent implementations may be implemented from the present disclosure.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A page buffer circuit comprising:
a plurality of page buffer circuits; and
a plurality of cache latches connected with the plurality of page buffer circuits through a combined sensing node,
wherein each page buffer circuit of the plurality of page buffer circuits comprises a main latch connected with a respective sensing node,
wherein the main latch comprises
a first transistor connected with a corresponding sensing node and configured to be driven by a monitoring signal,
a first latch circuit configured to latch data, and
a second transistor connected with the first transistor and configured to be driven by a voltage level of a node latching data in the first latch circuit, and
wherein a parasitic capacitor is connected between the first transistor and the second transistor, the parasitic capacitor arranged to provide a parasitic capacitance caused by a junction of the first transistor and the second transistor.

2. The page buffer circuit of claim 1, wherein the page buffer circuit is configured to precharge a node connected with the first transistor and the second transistor before a data dumping operation of transferring data, stored in the main latch, to a second latch.

3. The page buffer circuit of claim 2, wherein each page buffer circuit of the plurality of page buffer circuits comprises a precharge transistor configured to be driven by a load signal and connected between a corresponding sensing node and a precharge voltage line,
wherein the page buffer circuit is configured to precharge the node connected with the first transistor and the second transistor,
wherein the page buffer circuit is configured to precharge a corresponding sensing node based on the corresponding sensing node being connected with the precharge voltage line by an activated load signal, and
wherein the page buffer circuit is configured to precharge the node connected with the first transistor and the second transistor based on the corresponding sensing node being discharged by an activated monitoring signal.

4. The page buffer circuit of claim 2, wherein, based on the number of activated monitoring signals being more than or equal to a predetermined number, the page buffer circuit is configured to precharge the node connected with the first transistor and the second transistor before the data dumping operation of transferring the data, stored in the main latch, to the second latch.

5. The page buffer circuit of claim 1, wherein each cache latch of the plurality of cache latches comprises:
a third transistor connected with the combined sensing node and configured to be driven by a monitoring signal;
a second latch circuit configured to latch data; and
a fourth transistor connected with the third transistor and configured to be driven by a voltage level of a node latching data in the second latch circuit, and
wherein a second parasitic capacitor is connected between the third transistor and the fourth transistor, the second parasitic capacitor arranged to provide a second parasitic capacitance caused by a junction of the third transistor and the fourth transistor.

6. The page buffer circuit of claim 5, wherein the page buffer circuit is configured to precharge a node connected with the third transistor and the fourth transistor before a data dumping operation of transferring data, stored in the cache latch, to a second latch.

7. The page buffer circuit of claim 6, wherein each cache latch of the plurality of cache latches comprises a precharge transistor configured to be driven by a combined sensing node load signal and connected between the combined sensing node and a precharge voltage line,
wherein the page buffer circuit is configured to precharge the node connected with the first transistor and the second transistor,
wherein the page buffer circuit is configured to precharge a corresponding sensing node based on the corresponding sensing node being connected with the precharge voltage line by an activated combined sensing node load signal, and
wherein the page buffer circuit is configured to precharge the node connected with the third transistor and the fourth transistor based on the corresponding sensing node being discharged by an activated monitoring signal.

8. The page buffer circuit of claim 1, wherein the main latch comprises:
an N-channel transistor connected with a node connecting the first transistor with the second transistor and configured to be driven by a bit line reference voltage line; and
a P-channel transistor connected between the N-channel transistor and a precharge voltage line and configured to be driven by a voltage level of a node latching data in the first latch circuit.

9. A memory device comprising:
a memory cell array including a plurality of memory cells; and
a page buffer circuit including a plurality of page buffer circuits respectively connected with the plurality of memory cells through a plurality of bit lines and a plurality of cache latches, the plurality of cache latches respectively corresponding to the plurality of page buffer circuits,
wherein each page buffer circuit of the plurality of page buffer circuits comprises a main latch connected with a corresponding sensing node,
wherein the main latch comprises
a first transistor connected with a corresponding sensing node and configured to be driven by a monitoring signal,
a first latch circuit configured to latch data, and
a second transistor connected with the first transistor and configured to be driven by a voltage level of a node latching data in the first latch circuit, and
wherein a parasitic capacitor is connected between the first transistor and the second transistor, the parasitic capacitor arranged to provide a parasitic capacitance caused by a junction of the first transistor and the second transistor.

10. The memory device of claim 9, wherein the page buffer circuit is configured to precharge a node connected with the first transistor and the second transistor before a data dumping operation of transferring data, stored in the main latch, to a second latch.

11. The memory device of claim 10, wherein each page buffer circuit of the plurality of page buffer circuits comprises a precharge transistor configured to be driven by a load signal and connected between a corresponding sensing node and a precharge voltage line,
wherein the page buffer circuit is configured to precharge the node connected with the first transistor and the second transistor,
wherein the page buffer circuit is configured to precharge a corresponding sensing node based on the corresponding sensing node being connected with the precharge voltage line by an activated load signal, and
wherein the page buffer circuit is configured to precharge the node connected to the first transistor and the second transistor based on the corresponding sensing node being discharged by an activated monitoring signal.

12. The memory device of claim 10, wherein, based on the number of activated monitoring signals being more than or equal to a predetermined number, the page buffer circuit is configured to precharge the node connected with the first transistor and the second transistor before the data dumping operation of transferring the data, stored in the main latch, to the second latch.

13. The memory device of claim 9, wherein each cache latch of the plurality of cache latches comprises:
a third transistor connected with a combined sensing node and configured to be driven by a monitoring signal;
a second latch circuit configured to latch data; and
a fourth transistor connected with the third transistor and configured to be driven by a voltage level of a node latching data in the second latch circuit, and
wherein a second parasitic capacitor is connected between the third transistor and the fourth transistor, the second parasitic capacitor arranged to provide a second parasitic capacitance caused by a junction of the third transistor and the fourth transistor.

14. The memory device of claim 13, wherein the page buffer circuit is configured to precharge a node connected with the third transistor and the fourth transistor before a data dumping operation of transferring data, stored in the cache latch, to a second latch.

15. The memory device of claim 14, wherein each cache latch of the plurality of cache latches comprises a precharge transistor configured to be driven by a combined sensing node load signal and connected between the combined sensing node and a precharge voltage line,
wherein the page buffer circuit is configured to precharge the node connected with the first transistor and the second transistor,
wherein the page buffer circuit is configured to precharge a corresponding sensing node based on the corresponding sensing node being connected with the precharge voltage line by an activated combined sensing node load signal, and
wherein the page buffer circuit is configured to precharge the node connected with the third transistor and the fourth transistor based on the corresponding sensing node being discharged by an activated monitoring signal.

16. The memory device of claim 9, wherein the main latch comprises:
an N-channel transistor connected with a node connecting the first transistor with the second transistor and configured to be driven by a bit line reference voltage line; and
a P-channel transistor connected between the N-channel transistor and a precharge voltage line and configured to be driven by a voltage level of a node latching data in the first latch circuit.

17. A memory device comprising:
a first semiconductor layer including a plurality of memory cells respectively connected with a plurality of bit lines; and
a second semiconductor layer disposed in a vertical direction with respect to the first semiconductor layer, the second semiconductor layer including a page buffer circuit,
wherein the page buffer circuit comprises:
a main region where a plurality of page buffer circuits are disposed; and
a cache region where a plurality of cache latches corresponding to the plurality of page buffer circuits are disposed,
wherein each page buffer circuit of the plurality of page buffer circuits comprises a main latch connected with a corresponding sensing node,
wherein the main latch comprises:
a first transistor connected with a corresponding sensing node and configured to be driven by a monitoring signal;
a first latch circuit configured to latch data; and
a second transistor connected with the first transistor and configured to be driven by a voltage level of a node latching data in the first latch circuit, and
wherein a parasitic capacitor is connected between the first transistor and the second transistor, the parasitic capacitor arranged to provide a parasitic capacitance caused by a junction of the first transistor and the second transistor.

18. The memory device of claim 17, wherein the page buffer circuit is configured to precharge a node connected with the first transistor and the second transistor before a data dumping operation of transferring data, stored in the main latch, to a second latch.

19. The memory device of claim 18, wherein, based on the number of activated monitoring signals being more than or equal to a predetermined number, the page buffer circuit is configured to precharge the node connected with the first transistor and the second transistor before the data dumping operation of transferring the data, stored in the main latch, to the second latch.

20. The memory device of claim 17, wherein the main latch comprises:
an N-channel transistor connected with a node connecting the first transistor with the second transistor and configured to be driven by a bit line reference voltage line; and
a P-channel transistor connected between the N-channel transistor and a precharge voltage line and configured to be driven by a voltage level of a node latching data in the first latch circuit.
